(19) United States
(12) Patent Application Publication
(10) Pub. No.: US 2024/0282866 A1
(43) Pub. Date: Aug. 22, 2024

(54) PASSIVE ELEMENT AND ELECTRONIC DEVICE

(71) Applicant: Sumitomo Electric Device Innovations, Inc., Yokohama-shi, Kanagawa (JP)

(72) Inventors: Kento KAWASAKI, Yokohama-shi (JP); Takuma MORI, Yokohama-shi (JP)

(73) Assignee: Sumitomo Electric Device Innovations, Inc., Yokohama-shi, Kanagawa (JP)

(21) Appl. No.: 18/568,570

(22) PCT Filed: Jun. 9, 2022
(86) PCT No.: PCT/JP2022/023341

§ 371 Date: Dec. 8, 2023

(30) Foreign Application Priority Data
Jun. 11, 2021 (JP) 2021-098158

(51) Int. Cl. H01L 29/94; H01L 23/00; H01L 25/18; H01L 29/417; H01L 29/66

(52) U.S. Cl. CPC H01L 29/94; H01L 24/05; H01L 24/06; H01L 25/18; H01L 29/417; H01L 29/66181; H01L 29/66196; H01L 24/03; H01L 24/29; H01L 24/32; H01L 24/48; H01L 24/49; H01L 24/73; H01L 2224/03444; H01L 2224/03472; H01L 2224/05553; H01L 2224/05644; H01L 2224/05666; H01L 2224/05669; H01L 2224/0603; H01L 2224/06181; H01L 2224/29111; H01L 2224/29139; H01L 2224/29144; H01L 2224/32245; H01L 2224/48091; H01L 2224/48106; H01L 2224/4813; H01L 2224/48137; H01L 2224/48247; H01L 2224/4903; H01L 2224/49052; H01L 2224/49096; H01L 2224/49109; H01L 2224/49111; H01L 2224/49112; H01L 2224/49175; H01L 2224/73265; H01L 2924/0132; H01L 2924/1205

(57) ABSTRACT

The passive element includes a semiconductor substrate, a first insulating film, a first metal pad, a first conductor, and a first conductive film. The semiconductor substrate has p-type or n-type conductivity, and has a main surface and a back surface. The first insulating film is provided on a first region in the main surface of the semiconductor substrate. The first metal pad is provided on the first insulating film. The first conductor extends from the first metal pad in the first direction. The first conductive film is provided on a second region adjacent to the first region in a first direction in the main surface of the semiconductor substrate. The first conductive film is in ohmic contact with the main surface of the semiconductor substrate, and has an electrical resistivity lower than an electrical resistivity of the semiconductor substrate.

### TECHNICAL FIELD

The present disclosure relates to a passive element and an electronic device. This application is based upon and claims the benefit of priority from Japanese Application No. 2021-098158 filed on Jun. 11, 2021, the entire contents of which are incorporated herein by reference.

### BACKGROUND ART

Patent Literature 1 discloses a configuration of a semiconductor device and a package thereof. The semiconductor device includes a semiconductor chip and a circuit board. The semiconductor chip and the circuit board are housed in a package. The circuit board is made of ceramic or the like. On the circuit board, there are formed a circuit for distributing and combining power, a circuit for matching input/output impedance of a transistor, and surface wiring for connecting the circuit for distributing and combining power and the circuit for matching input/output impedance to each other. The package has an input lead and an input wiring pad. The circuit board is connected to the input wiring pad by a bonding wire. The circuit board is connected to the semiconductor chip by another bonding wire.

### CITATION LIST

### Patent Literature

[Patent Literature 1] Japanese Unexamined Patent Publication No. H10-294401

### SUMMARY OF INVENTION

### Technical Problem

A passive element such as a capacitor may be used in an electronic device such as an amplification device. For example, in the case of an electronic device that inputs and outputs a high-frequency signal having a frequency equal to or higher than 100 MHz, a capacitor is used to match an input impedance and an output impedance of a semiconductor element incorporated in the electronic device. As an example, a member including a ceramic substrate and a metal pad provided on the ceramic substrate is disposed on a conductive base as in the configuration described in Patent Literature 1, so that capacitance can be obtained between the metal pad and the base. In this case, the base is defined at a constant potential, for example, a common ground potential with the semiconductor element, and the metal pad is connected with a signal input terminal or a signal output terminal of the semiconductor element by a wire or the like.

Here, a semiconductor substrate on which an insulating film is formed is considered to be used instead of the ceramic substrate. For example, a capacitor in which a silicon oxide film is formed on a silicon substrate and a metal pad is provided thereon is called a MOS capacitor. When a capacitor having an insulating film on a semiconductor substrate and further having a metal pad thereon is used in a high-frequency electronic device, the following problem occurs. When a signal propagates through the metal pad, a return current flows through the conductive base on which the capacitor is mounted. When the signal frequency is relatively low, the return current mainly flows inside the base and hardly flows in the semiconductor substrate. On the other hand, when the signal frequency is relatively high, for example, equal to or higher than the 100 MHz, the return current mainly flows near the upper surface of the semiconductor substrate due to the so-called skin effect. In this case, the return current is affected by the electrical resistance of the semiconductor substrate, and the high-frequency signal is attenuated.

An object of the present disclosure is to suppress attenuation of a high-frequency signal in a passive element having an insulating film on a semiconductor substrate and having a metal pad on the insulating film.

### Solution to Problem

A first passive element according to the present disclosure includes a semiconductor substrate, a first insulating film, a first metal pad, a first conductor, and a first conductive film. The semiconductor substrate has p-type or n-type conductivity, and has a main surface and a back surface. The first insulating film is provided on a first region of the main surface of the semiconductor substrate. The first metal pad is a metallic pad provided on the first insulating film. The first conductor extends from the first metal pad in the first direction. The first conductive film is provided on a second region adjacent to the first region in a first direction in the main surface of the semiconductor substrate. The first conductive film is in ohmic contact with the main surface of the semiconductor substrate, and has an electrical resistivity lower than an electrical resistivity of the semiconductor substrate.

A second passive element according to the present disclosure includes a semiconductor substrate, a conductive film, a first insulating film, a first metal pad, and a first conductor. The semiconductor substrate has p-type or n-type conductivity, and has a main surface and a back surface. The conductive film is provided on a region including a first region and a second region adjacent to the first region in a first direction in the main surface of the semiconductor substrate. The conductive film is in ohmic contact with the main surface of the semiconductor substrate, and has an electrical resistivity lower than an electrical resistivity of the semiconductor substrate. The first insulating film is provided on the first region and on the conductive film. The first metal pad is a metallic pad provided on the first insulating film. The first conductor extends from the first metal pad in the first direction.

An electronic device according to the present disclosure includes a housing, a semiconductor element, a passive element, a second conductor, and a third conductor. The housing includes a signal terminal and a conductive base. The semiconductor element has a signal electrode and a ground electrode conductively bonded to the base, and is mounted on the base. The passive element includes a semiconductor substrate, a first insulating film, a first metal pad, a first conductor, a first conductive film, a second insulating film, and a second metal pad. The semiconductor substrate is mounted on a base, has p-type or n-type conductivity, and has a main surface and a back surface. The first insulating film is provided on a first region in the main surface of the semiconductor substrate. The first metal pad is provided on the first insulating film. The first conductor is connected to the first metal pad and extends from the first metal pad in the first direction. The first conductive film is provided on the second region. The second region is adjacent to the first region in the first direction on the main surface of the semiconductor substrate and is located under the first conductor. The first conductive film is in ohmic contact with the main surface of the semiconductor substrate, and has an electrical resistivity lower than an electrical resistivity of the semiconductor substrate. The second insulating film is provided on a third region adjacent to the second region in the first direction. The second metal pad is connected to the first conductor and is provided on the second insulating film. The second conductor electrically connects the first metal pad of the passive element and the signal terminal. The third conductor electrically connects the second metal pad of the passive element and the signal electrode of the semiconductor element.

### Advantageous Effects of Invention

According to the present disclosure, attenuation of a high-frequency signal can be suppressed in a passive element having an insulating film on a semiconductor substrate and having a metal pad on the insulating film.

### BRIEF DESCRIPTION OF DRAWINGS

FIG. 1 is a cross-sectional view illustrating a structure of a capacitor according to a first embodiment.

FIG. 2 is a plan view of the capacitor according to the first embodiment.

FIG. 3 is a schematic diagram illustrating a configuration example of a conductive film in a case where the semiconductor substrate is a silicon substrate.

FIG. 4 is a schematic diagram illustrating a configuration example of a conductive film in a case where the semiconductor substrate is a silicon substrate.

FIG. 5 is a cross-sectional view showing a process in a method of manufacturing a capacitor.

FIG. 6 is a cross-sectional view showing a process in the method for manufacturing the capacitor.

FIG. 7 is a cross-sectional view showing a process in the method for manufacturing the capacitor.

FIG. 8 is a cross-sectional view showing a process in the method for manufacturing the capacitor.

FIG. 9 is a cross-sectional view showing a process in the method for manufacturing the capacitor.

FIG. 10 is a cross-sectional view showing a process in the method for manufacturing the capacitor.

FIG. 11 is a cross-sectional view showing a process in the method for manufacturing the capacitor.

FIG. 12 is a cross-sectional view showing a process in the method for manufacturing the capacitor.

FIG. 13 is a cross-sectional view showing a process in the method for manufacturing the capacitor.

FIG. 14 is a cross-sectional view showing a process in the method for manufacturing the capacitor.

FIG. 15 is a cross-sectional view showing a process in the method for manufacturing the capacitor.

FIG. 16 is a cross-sectional view showing a process in the method for manufacturing the capacitor.

FIG. 17 is a cross-sectional view showing a process in the method for manufacturing the capacitor.

FIG. 18 is a cross-sectional view showing a process in the method for manufacturing the capacitor.

FIG. 19 is a cross-sectional view showing a process in the method for manufacturing the capacitor.

FIG. 20 is a cross-sectional view showing a process in the method for manufacturing the capacitor.

FIG. 21 is a cross-sectional view showing a process in the method for manufacturing the capacitor.

FIG. 22 is a cross-sectional view showing a process in the method for manufacturing the capacitor.

FIG. 23 is a cross-sectional view showing a process in the method for manufacturing the capacitor.

FIG. 24 is a cross-sectional view illustrating a structure of a ceramic capacitor.

FIG. 25 is a cross-sectional view showing a capacitor having an insulating film on a semiconductor substrate.

FIG. 26 is a diagram showing a path of a return current.

FIG. 27 is a graph showing the relationship between the skin thickness and the signal frequency when the semiconductor substrate is made of silicon.

FIG. 28 is a diagram showing an example in which two capacitors having the configuration shown in FIG. 25 are arranged.

FIG. 29 is a diagram showing a configuration in which the thickness of the insulating film is reduced and the width of the semiconductor substrate is reduced.

FIG. 30 is a diagram showing a configuration in which two capacitors share a semiconductor substrate.

FIG. 31 is a diagram showing a return current path in the capacitor of the first embodiment.

FIG. 32 is a graph showing a S21 transmission characteristic of an RF amplifier.

FIG. 33 is a cross-sectional view showing a structure of a capacitor according to a first modification.

FIG. 34 is a plan view of a capacitor according to the first modification.

FIG. 35 is a plan view showing a capacitor according to a second modification.

FIG. 36 is a plan view showing an aspect in which a wire is connected to a metal pad of the capacitor according to the second modification.

FIG. 37 is a plan view showing an aspect in which a wire is connected to a metal pad of the capacitor according to the second modification.

FIG. 38 is a cross-sectional view showing a structure of a capacitor according to a third modification.

FIG. 39 is a plan view of a capacitor according to a third modification.

FIG. 40 is a plan view showing a configuration of an electronic device according to a second embodiment.

FIG. 41 is a cross-sectional view taken along line XXXXI-XXXXI of FIG. 40.

FIG. 42 is a plan view showing the configuration of the electronic device according to the third embodiment.

### DESCRIPTION OF EMBODIMENTS

### Description of Embodiments of the Present Disclosure

A first passive element according to one embodiment includes a semiconductor substrate, a first insulating film, a first metal pad, a first conductor, and a first conductive film. The semiconductor substrate has p-type or n-type conductivity, and has a main surface and a back surface. The first insulating film is provided on a first region in the main surface of the semiconductor substrate. The first metal pad is a metallic pad provided on the first insulating film. The first conductor extends from the first metal pad in the first direction. The first conductive film is provided on a second region adjacent to the first region in a first direction in the main surface of the semiconductor substrate. The first conductive film is in ohmic contact with the main surface of the semiconductor substrate, and has an electrical resistivity lower than an electrical resistivity of the semiconductor substrate.

When the first passive element is mounted on a conductive base, the semiconductor substrate is electrically connected to the base and has the same potential as the base, so that capacitance is obtained between the semiconductor substrate and the first metal pad. This capacitance depends on the area of the first metal pad and the distance from the first metal pad to the semiconductor substrate, typically the thickness of the first insulating film. Therefore, when the first metal pad is connected to a signal terminal of a semiconductor element by a bonding wire, an input impedance or an output impedance at the signal terminal can be matched by appropriately determining the area of the first metal pad and the distance from the first metal pad to the semiconductor substrate.

Here, a case where the first conductive film does not exist is considered. As described above, when the signal frequency is relatively high, the return current mainly flows in the upper surface of the semiconductor substrate, that is, in the vicinity of the main surface due to the so-called skin effect. Then, the return current is affected by the electrical resistance of the semiconductor substrate, and the high-frequency signal is attenuated. In order to reduce the degree of attenuation of the high-frequency signal, it is effective to reduce the width of the semiconductor substrate in the traveling direction of the return current as much as possible, in other words, to shorten the path of the return current in the semiconductor substrate as much as possible. However, as the width of the semiconductor substrate is reduced, cracks are more likely to occur in the semiconductor substrate, and rotational misalignment is more likely to occur during assembly of the electronic device. Thus, handling of the passive element becomes difficult.

In order to solve this problem, in the first passive element, the first conductive film is provided on the main surface of the semiconductor substrate in addition to the first insulating film and the first metal pad for obtaining capacitance. The first conductive film is provided in parallel with the first insulating film and the first metal pad, and is in ohmic contact with the main surface of the semiconductor substrate. The high-frequency return current mainly flows in the vicinity of the main surface of the semiconductor substrate in the first region, but mainly flows in the first conductive film in ohmic contact with the main surface of the semiconductor substrate in the second region. Accordingly, it is possible to shorten the path of the return current in the semiconductor substrate while securing a sufficient width of the semiconductor substrate. Therefore, according to the first passive element, attenuation of a high-frequency signal can be suppressed.

The first passive element may further include a second insulating film provided on a third region aligned with the second region in the main surface of the semiconductor substrate, and a second metal pad provided on the second insulating film. The second region may be located between the first region and the third region. In this case, by connecting the first metal pad and the second metal pad by a wire, a matching circuit having two stages of capacitor portions and an inductance therebetween can be realized by a single capacitor element.

The first metal pad may have a first protrusion protruding toward the second metal pad. The first conductive film may have a first indentation that surrounds the first protrusion from three sides. In this case, it is possible to bond one end of the wire connecting the first metal pad and the second metal pad to the first protrusion, and the adjustable range of the length of the wire is expanded. In addition, the width of the first region in the current traveling direction can be kept narrow in the other portion of the first region except for the portion immediately below the first protrusion. This makes it possible to keep the width of the second region, that is, the width of the first conductive film wide. Therefore, it is possible to effectively reduce the attenuation of the high-frequency signal while increasing the degree of freedom of the length of the wire, that is, the magnitude of the inductance.

The second metal pad may have a second protrusion protruding toward the first protrusion. The first conductive film may further include a second indentation that surrounds the second protrusion from three sides. In this case, the other end of the wire connecting the first metal pad and the second metal pad can be bonded to the second protrusion, and the adjustable range of the length of the wire is further expanded. In addition, the width of the third region in the current traveling direction can be kept narrow in the portion of the third region other than the portion immediately below the second protrusion. This makes it possible to keep the width of the second region, that is, the width of the first conductive film wide. Therefore, it is possible to effectively reduce the attenuation of the high-frequency signal while increasing the degree of freedom of the length of the wire, that is, the magnitude of the inductance.

The first passive element may further include a second conductive film, a third insulating film, and a third metal pad. The second conductive film is provided on the fourth region in the main surface of the semiconductor substrate. The second conductive film is in ohmic contact with the main surface of the semiconductor substrate, and has an electrical resistivity lower than an electrical resistivity of the semiconductor substrate. The third insulating film is provided on the fifth region in the main surface of the semiconductor substrate. The third metal pad is a metallic pad provided on the third insulating film. The first region, the second region, the third region, the fourth region, and the fifth region may be arranged in this order along the first direction. In this case, by connecting the first metal pad and the second metal pad by a wire and connecting the second metal pad and the third metal pad by another wire, a matching circuit having three stages of capacitor portions and inductances therebetween can be realized by a single capacitor element.

A width of the first conductive film in the first direction may be larger than a width of the first metal pad in the same direction. By reducing the width of the first metal pad and increasing the width of the first conductive film in this manner, in the return current path, the portion in the semiconductor substrate can be shortened, and the portion in the first conductive film can be lengthened. Therefore, attenuation of the high-frequency signal can be effectively reduced while securing a sufficient width of the semiconductor substrate.

The first conductive film may be made of a metal. In this case, the first conductive film having an electrical resistivity lower than the electrical resistivity of the semiconductor substrate can be easily formed.

The semiconductor substrate may be a silicon substrate, and the first conductive film may include a Ti film in contact with the silicon substrate and an Au film provided on the Ti film. In this case, the semiconductor substrate and the first conductive film are firmly bonded to each other, and the reliability of the passive element can be enhanced. Note that the semiconductor substrate may be a gallium arsenide (GaAs) substrate.

A second passive element according to one embodiment includes a semiconductor substrate, a conductive film, a first insulating film, a first metal pad, and a first conductor. The semiconductor substrate has p-type or n-type conductivity, and has a main surface and a back surface. The conductive film is provided on a region including a first region and a second region adjacent to the first region in a first direction in the main surface of the semiconductor substrate. The conductive film is in ohmic contact with the main surface of the semiconductor substrate, and has an electrical resistivity lower than an electrical resistivity of the semiconductor substrate. The first insulating film is provided on the first region and on the conductive film. The first metal pad is a metal pad provided on the first insulating film. The first conductor extends from the first metal pad in the first direction.

When the second passive element is mounted on a conductive base, the conductive film is electrically connected to the base via the semiconductor substrate and has the same potential as the base, so that capacitance is obtained between the conductive film and the first metal pad. This capacitance depends on the area of the first metal pad and the distance from the first metal pad to the conductive film, typically the thickness of the first insulating film. Therefore, when the first metal pad is connected to a signal terminal of a semiconductor element by a bonding wire, an input impedance or an output impedance at the signal terminal can be matched by appropriately determining the area of the first metal pad and the distance from the first metal pad to the conductive film.

In the second passive element, the conductive film in contact with the main surface of the semiconductor substrate is provided from the first region where the first insulating film and the first metal pad for obtaining capacitance are provided to the second region. Therefore, the high-frequency return current mainly flows in the conductive film in both the first region and the second region. Accordingly, it is possible to shorten the path of the return current in the semiconductor substrate while securing a sufficient width of the semiconductor substrate. Therefore, according to the second passive element, attenuation of a high-frequency signal can be suppressed.

The second passive element may further include a second insulating film provided on the conductive film on a third region adjacent to the second region in the first direction in the main surface of the semiconductor substrate, and a second metal pad provided on the second insulating film. The second region may be located between the first region and the third region. In this case, by connecting the first metal pad and the second metal pad by a wire, a matching circuit having two stages of capacitor portions and an inductance therebetween can be realized by a single capacitor element.

The first passive element and the second passive element may further include a back surface metal film provided on the back surface of the semiconductor substrate and in contact with the semiconductor substrate. In this case, the back surface metal film and the base can be easily and firmly bonded to each other using a conductive paste or the like.

The electrical resistivity of the semiconductor substrate may be 1.0×10⁻⁴ Ω·cm or more and 1 Ω·cm or less. The first passive element and the second passive element are particularly effective when a semiconductor substrate having such an electrical resistivity is used.

The first metal pad may extend along a second direction that intersects the first direction, and a length of the first metal pad in the second direction may be greater than a width of the first metal pad in the first direction. As described above, since the first metal pad has a planar shape elongated in the second direction intersecting with the first direction that is a current traveling direction, current densities of the signal current and the return current are suppressed, and thus the passive element can be used in an electronic device for high power. In this case, the length of the first metal pad in the second direction may be ten times or more the width of the first metal pad in the first direction.

A first electronic device according to one embodiment includes a housing, a semiconductor element, and any one of the passive elements described above. The housing includes a signal terminal and a conductive base. The semiconductor element is mounted on the base. The semiconductor element includes a signal electrode and a ground electrode, and the ground electrode is conductively bonded to the base. The passive element is mounted on the base. The first metal pad of the passive element is electrically connected with the signal terminal by a first wire, and electrically connected to the signal electrode of the semiconductor element by a second wire. The semiconductor substrate of the passive element is conductively bonded to the base. According to this electronic device, attenuation of a high-frequency signal can be suppressed by including any one of the passive elements described above.

A second electronic device according to one embodiment includes a housing, a semiconductor element, a passive element, a second conductor, and a third conductor. The housing includes a signal terminal and a conductive base. The semiconductor element is mounted on the base. The semiconductor element includes a signal electrode and a ground electrode, and the ground electrode is conductively bonded to the base. The passive element includes a semiconductor substrate, a first insulating film, a first metal pad, a first conductor, a first conductive film, a second insulating film, and a second metal pad. The semiconductor substrate is mounted on a base, has p-type or n-type conductivity, and has a main surface and a back surface. The first insulating film is provided on a first region in the main surface of the semiconductor substrate. The first metal pad is provided on the first insulating film. The first conductor is connected to the first metal pad and extends from the first metal pad in the first direction. The first conductive film is provided on the second region. The second region is adjacent to the first region in the first direction in the main surface of the semiconductor substrate and is located under the first conductor. The first conductive film is in ohmic contact with the main surface of the semiconductor substrate, and has an electrical resistivity lower than an electrical resistivity of the semiconductor substrate. The second insulating film is provided on a third region adjacent to the second region in the first direction. The second metal pad is connected to the first conductor and is provided on the second insulating film. The second conductor electrically connects the first metal pad of the passive element and the signal terminal. The third conductor electrically connects the second metal pad of the passive element and the signal electrode of the semiconductor element. According to this electronic device, attenuation of a high-frequency signal can be suppressed.

### Details of Embodiment of Present Invention

Specific examples of the passive element and the electronic device of the present disclosure will be described below with reference to the drawings. The present invention is not limited to these examples, but is defined by the claims and is intended to include all modifications within the meaning and range equivalent to the claims. In the following description, the same reference numerals are given to the same elements in the description of the drawings, and redundant description will be omitted.

### First Embodiment

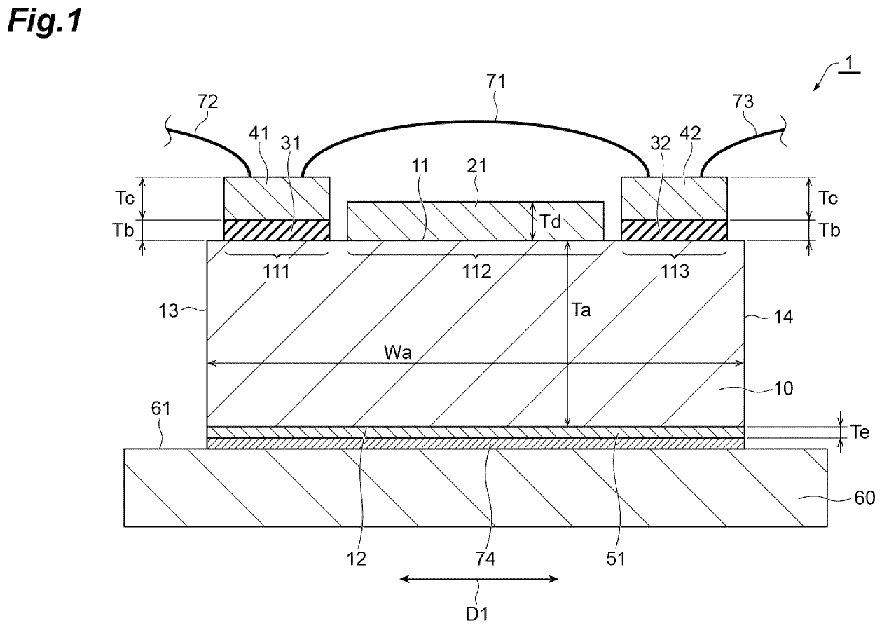

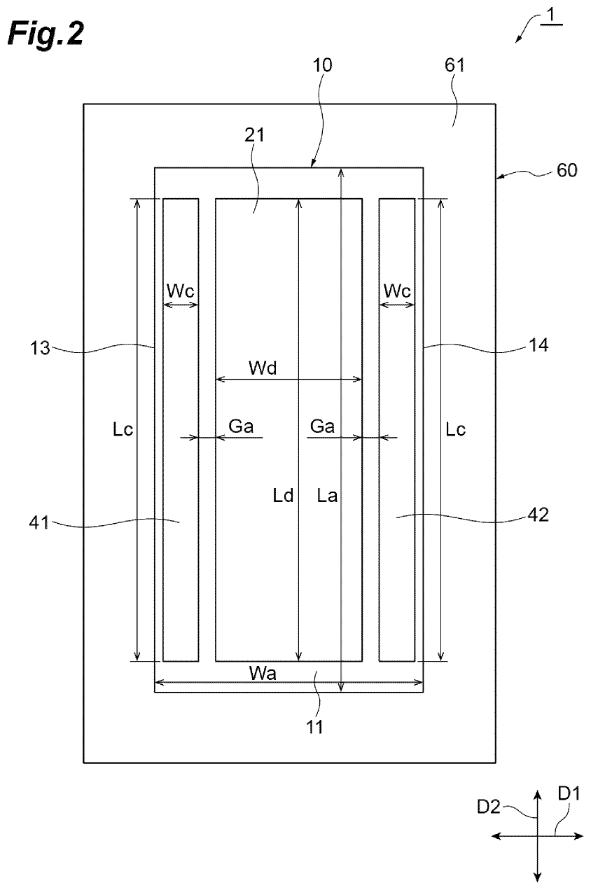

FIG. 1 is a cross-sectional view showing a structure of a capacitor 1 as a passive element according to a first embodiment. FIG. 2 is a plan view of the capacitor 1. The capacitor 1 is used to match one or both of an input impedance and an output impedance of a semiconductor element in an electronic device such as an amplification device. The capacitor 1 is mounted on a conductive base 60 included in the electronic device. The capacitor 1 includes a semiconductor substrate 10, a conductive film 21 (first conductive film), an insulating film 31 (first insulating film), an insulating film 32 (second insulating film), a metal pad 41 (first metal pad), a metal pad 42 (second metal pad), and a back surface metal film 51. The base 60 is made of metal, for example, and mainly contains copper (Cu) in one example. The base 60 has a flat mounting surface 61. The base 60 is larger than the capacitor 1 in plan view (in other words, as viewed from the normal direction of the mounting surface 61).

The semiconductor substrate 10 is a substantially rectangular parallelepiped member. The semiconductor substrate 10 has p-type or n-type conductivity. In one example, the semiconductor substrate 10 is a p-type or n-type silicon (Si) substrate. Alternatively, the semiconductor substrate 10 may be a p-type or n-type GaAs substrate. The electrical resistivity of the semiconductor substrate 10 is, for example, 1.0×10⁻⁴ Ω·cm or more and 1 Ω·cm or less. When the semiconductor substrate 10 is the silicon substrate, such an electric resistivity can be achieved by setting the n-type or p-type impurity concentration to, for example, 10¹⁵ cm⁻³ or more and 10²¹ cm⁻³ or less.

The semiconductor substrate 10 has a main surface 11, a back surface 12 facing away from the main surface 11, and a pair of side surfaces 13, 14. The normal direction of the main surface 11 coincides with the normal direction of the mounting surface 61 and the thickness direction of the semiconductor substrate 10. The back surface 12 is parallel to the main surface 11. The pair of side surfaces 13, 14 face each other in a direction D1 (first direction) along the mounting surface 61. The pair of side surfaces 13, 14 are parallel to each other and perpendicular to the main surface 11 and the back surface 12.

The thickness Ta of the semiconductor substrate 10 is, for example, 50 μm or more and 500 μm or less, and is 200 μm in one embodiment. The width Wa of the semiconductor substrate 10 in the direction D1 is, for example, 400 μm or more and 2500 μm or less, and is 1500 μm in one embodiment. The ratio (Ta/Wa) of the height to the width of the semiconductor substrate 10 is, for example, 0.02 or more and 1.25 or less, and is 0.13 in one embodiment. The length La of the semiconductor substrate 10 in a direction D2 (second direction) perpendicular to the direction D1 and along the mounting surface 61 is, for example, 1000 μm or more and 8000 μm or less, and is 6200 μm in one embodiment. The ratio (Wa/La) of the width to the length of the semiconductor substrate 10 is, for example, 0.05 or more and 2.5 or less, and is 0.24 in one embodiment. As described above, the length La of the semiconductor substrate 10 is larger than the width Wa of the semiconductor substrate 10.

As shown in FIG. 1, the main surface 11 includes a first region 111, a second region 112, and a third region 113. The first region 111, the second region 112, and the third region 113 are provided spaced apart from each other and arranged in this order in the direction D1. That is, in the direction D1, the second region 112 is located between the first region 111 and the third region 113. The second region 112 is adjacent to the first region 111 in the direction D1. The third region 113 is adjacent to the second region 112 in the direction D1. The first region 111 is provided along the side surface 13 of the semiconductor substrate 10. The third region 113 is provided along the side surface 14 of the semiconductor substrate 10.

The insulating film 31 is provided on the first region 111 of the main surface 11. The insulating film 32 is provided on the third region 113 of the main surface 11. The insulating films 31 and 32 are, for example, inorganic insulating films, and are silicon oxide films (SiO₂ films) in one example. When the semiconductor substrate 10 is a silicon substrate, the silicon oxide film may be a film formed by oxidation of the surface of the silicon substrate. The thickness Tb of the insulating films 31 and 32 is, for example, 0.1 μm or more and 5 μm or less, and is 1 μm in one embodiment. The insulating film 31 is provided along the side surface 13 of the semiconductor substrate 10. The insulating film 32 is provided along the side surface 14 of the semiconductor substrate 10.

The metal pads 41 and 42 are metallic pads for wire bonding. The metal pad 41 is provided on the insulating film 31 and provided along the side surface 13 of the semiconductor substrate 10. That is, the insulating film 31 is interposed between the metal pad 41 and the semiconductor substrate 10. The metal pad 42 is provided on the insulating film 32 and provided along the side surface 14 of the semiconductor substrate 10. That is, the insulating film 32 is interposed between the metal pad 42 and the semiconductor substrate 10. The metal pads 41 and 42 are made of metal materials such as Au, Pt, and Ti.

When the capacitor 1 is used, one end of a wire 71 (first conductor) having conductivity is bonded to the upper surface of the metal pad 41, and the other end of the wire 71 is bonded to the upper surface of the metal pad 42. The wire 71 extends from the metal pad 41 along the direction D1. Accordingly, the metal pad 41 and the metal pad 42 are electrically connected to each other by the wire 71. The length of the wire 71 is, for example, 200 μm or more and 2000 μm or less, and is 1600 μm in one embodiment.

One end of another wire 72 (third conductor) having conductivity is bonded to the metal pad 41. The other end of the wire 72 is bonded to, for example, a signal electrode of a semiconductor element (not shown), that is, a signal input terminal or a signal output terminal. Accordingly, the metal pad 41 is electrically connected to the signal input terminal or the signal output terminal of the semiconductor element by the wire 72. One end of another wire 73 (second conductor) having conductivity is bonded to the metal pad 42. The other end of the wire 73 is bonded to, for example, a signal input terminal or a signal output terminal of a housing (not shown). Accordingly, the metal pad 42 is electrically connected to the signal input terminal or the signal output terminal of the housing by the wire 73.

The metal pads 41, 42 extend along the direction D2. The length Lc of the metal pads 41 and 42 in the direction D2 is larger than the width Wc of the metal pads 41 and 42 in the direction D1. The length Lc of the metal pads 41 and 42 may be 10 times or more the width Wc of the metal pads 41 and 42, or may be 30 times or more the width Wc. The length Lc of the metal pads 41 and 42 may be equal to or shorter than the length La of the semiconductor substrate 10.

The thickness Tc of the metal pads 41 and 42 is, for example, 0.5 μm or more and 10 μm or less, and is 5 μm in one embodiment. The width Wc of the metal pads 41 and 42 in the direction D1 is 100 μm or more and 1000 μm or less, for example, and is 200 μm in one embodiment. The ratio (Wc/Wa) of the width Wc of each of the metal pads 41 and 42 to the width Wa of the semiconductor substrate 10 is, for example, 0.05 or more and 0.66 or less, and is 0.13 in one embodiment. The length Lc of the metal pads 41 and 42 is 1000 μm or more and 8000 μm or less, for example, and is 6000 μm in one embodiment. The ratio (Wc/Lc) of the width to the length of the metal pads 41 and 42 is, for example, 0.01 or more and 0.5 or less, and is 0.033 in one embodiment.

The conductive film 21 is provided on the second region 112 of the main surface 11 and is in ohmic contact with the main surface 11. The conductive film 21 has an electric resistivity lower than an electric resistivity of the semiconductor substrate 10. The conductive film 21 is made of, for example, metal. In the direction D1, the conductive film 21 is disposed between the metal pad 41 and the metal pad 42. A gap is provided between the conductive film 21 and the metal pad 41, and the conductive film 21 and the metal pad 41 are insulated from each other. A gap is provided between the conductive film 21 and the metal pad 42, and the conductive film 21 and the metal pad 42 are insulated from each other.

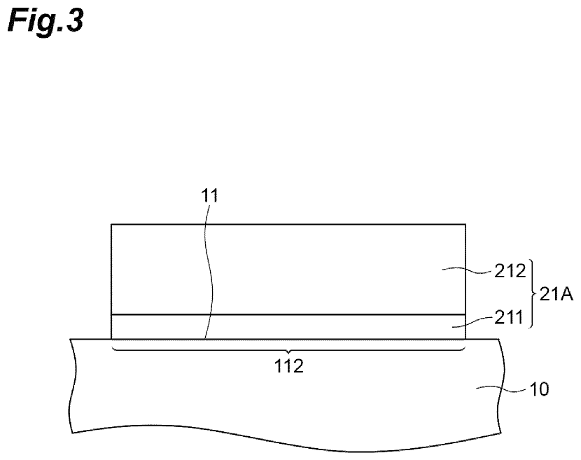

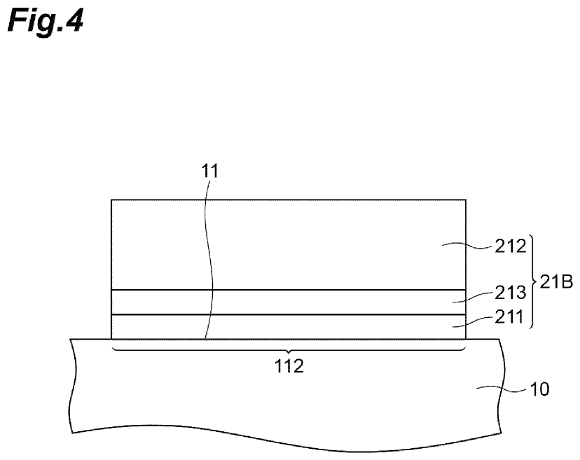

FIGS. 3 and 4 are schematic views each showing a configuration example of the conductive film 21 when the semiconductor substrate 10 is a silicon substrate. The conductive film 21A shown in FIG. 3 includes a Ti film 211 in contact with the silicon substrate, and a Au film 212 provided on the Ti film 211. The conductive film 21B shown in FIG. 4 further includes a Pt film 213 provided between the Ti film 211 and the Au film 212 in addition to the Ti film 211 and the Au film 212.

Reference is again made to FIGS. 1 and 2. The thickness Td of the conductive film 21 is, for example, 0.5 μm or more and 10 μm or less, and is 5 μm in one embodiment. The width Wd of the conductive film 21 in the direction D1 is, for example, 200 μm or more and 2000 μm or less, and is 1000 μm in one embodiment. The length Ld of the conductive film 21 in the direction D2 is, for example, 1000 μm or more and 8000 μm or less, and is 6000 μm in one embodiment. In the illustrated example, the length Ld of the conductive film 21 is equal to the length Lc of the metal pads 41 and 42, but the length Ld of the conductive film 21 may be longer than the length Lc of the metal pads 41 and 42. In other words, one end of the conductive film 21 may protrude from an imaginary line connecting one end of the metal pad 41 and one end of the metal pad 42. The ratio (Wd/Ld) of the width to the length of the conductive film 21 is, for example, 0.025 or more and 2.3 or less, and is 0.17 in one embodiment. As described above, the length Ld of the conductive film 21 is larger than the width Wd of the conductive film 21. The width Wd of the conductive film 21 is larger than the width Wc of the metal pads 41, 42. The ratio (Wc/Wd) of the width Wc of the metal pads 41, 42 to the width Wd of the conductive film 21 is, for example, 0.01 or more and 1.0 or less, and is 0.20 in one embodiment. The gaps Ga between the conductive film 21 and the metal pads 41, 42 are, for example, 5 μm or more and 200 μm or less, and are 50 μm in one embodiment. Gaps are also provided between the conductive film 21 and the insulating films 31, 32, and the main surface 11 of the semiconductor substrate 10 is exposed from the gaps. The conductive film 21 may be in contact with the insulating films 31, 32. In this case, the main surface 11 of the semiconductor substrate 10 is not exposed.

The back surface metal film 51 is a metallic film provided on the entire back surface 12 of the semiconductor substrate 10. The back surface metal film 51 is in contact with the semiconductor substrate 10. The back surface metal film 51 is made of metal materials such as Au, Pt, and Ti. The thickness Te of the back surface metal film 51 is, for example, 0.1 μm or more and 10 μm or less, and is 3 μm in one embodiment. The back surface metal film 51 is conductively bonded to the mounting surface 61 of the base 60 by the conductive paste 74. The conductive paste 74 is, for example, an AuSn paste or an Ag paste.

When the capacitor 1 is mounted on the conductive base 60, the semiconductor substrate 10 is electrically connected to the base 60 and has the same potential as the base 60, so that capacitance can be obtained between the semiconductor substrate 10 and the metal pads 41, 42. This capacitance depends on the area of the metal pads 41, 42 and the distance from the metal pads 41, 42 to the semiconductor substrate 10, typically the thickness of the insulating films 31, 32. Therefore, when the metal pads 41, 42 are connected to the signal terminal of the semiconductor element by the wires 71, 72, the input impedance or the output impedance at the signal terminal can be matched.

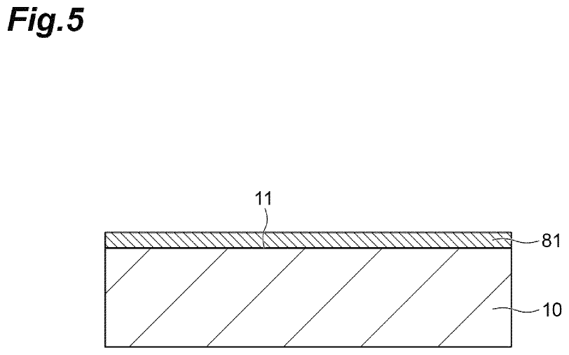

Here, a method of manufacturing the capacitor 1 will be described. FIGS. 5 to 23 are cross-sectional views showing processes in the method for manufacturing the capacitor 1. Here, a silicon substrate is used as the semiconductor substrate 10. First, in the processes shown in FIGS. 5 to 10, a mask made of an inorganic material is formed on the main surface 11 of the semiconductor substrate 10. Hereinafter, a case where the mask is made of SiN will be exemplified, but the mask material is not limited thereto.

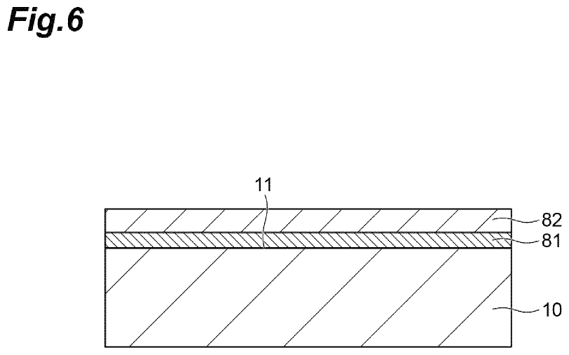

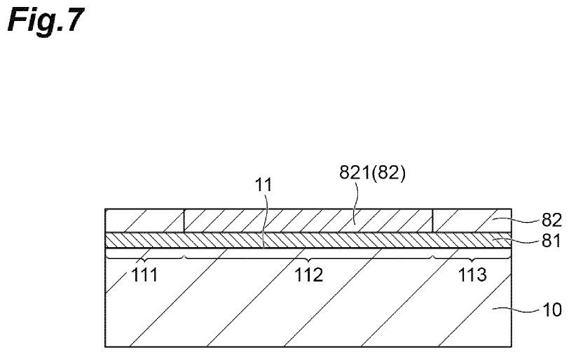

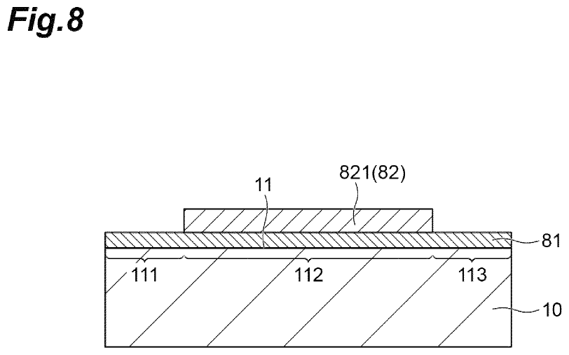

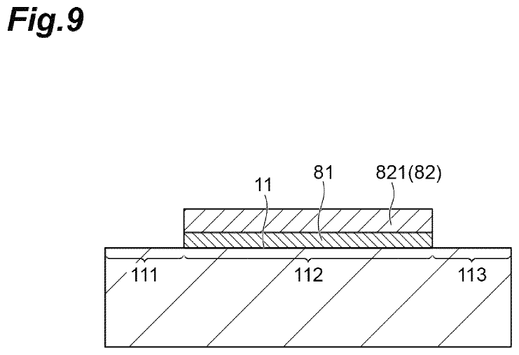

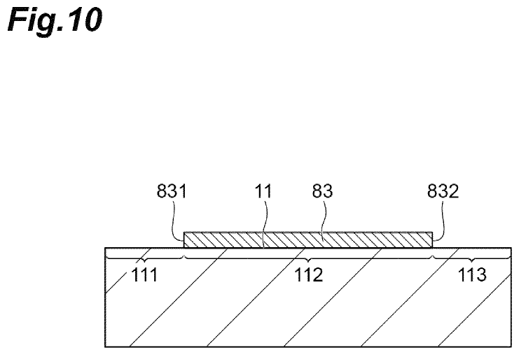

First, as shown in FIG. 5, an SiN film 81 is formed on the entire main surface 11 of the semiconductor substrate 10. For example, chemical vapor deposition (CVD) is used to form the SiN film 81. Next, as shown in FIG. 6, a resist 82 is applied to the entire surface of the SiN film 81. In the following description, a case where the resist 82 is a negative type will be exemplified, but the resist 82 may be a positive type. Subsequently, as shown in FIG. 7, a portion of the resist 82 on the second region 112 is exposed to form a photosensitive portion 821. Then, as shown in FIG. 8, portions of the resist 82 other than the photosensitive portion 821, that is, a portion on the first region 111 and a portion on the third region 113 are removed by development. Then, as shown in FIG. 9, portions of the SiN film 81 exposed from the resist 82, that is, a portion on the first region 111 and a portion on the third region 113, are removed by etching. Thereafter, as shown in FIG. 10, all of the resist 82 is peeled off and removed. Through the above-described process, the SiN mask 83 having openings 831, 832 on the first region 111 and the third region 113, respectively, is formed. The first region 111 and the third region 113 of the semiconductor substrate 10 are exposed through the openings 831, 832.

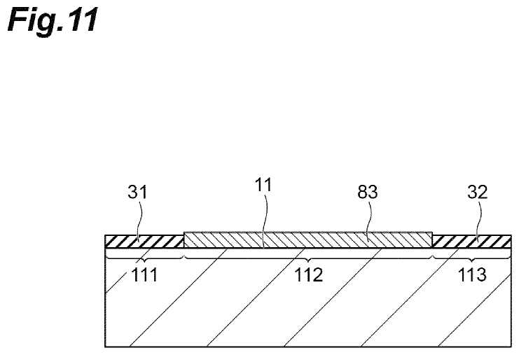

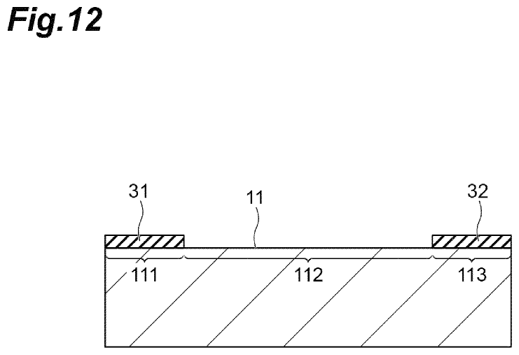

Subsequently, as shown in FIG. 11, the insulating film 31 is formed on the first region 111 of the semiconductor substrate 10 exposed in the opening 831 of the SiN mask 83. At the same time, the insulating film 32 is formed on the third region 113 of the semiconductor substrate 10 exposed in the opening 832 of the SiN mask 83. The insulating films 31, 32 can be formed using, for example, CVD. Alternatively, silicon oxide films may be formed as the insulating films 31, 32 by thermally oxidizing the exposed surface of the semiconductor substrate 10 which is a silicon substrate. Thereafter, the SiN mask 83 is removed by using a remover. The remover is, for example, a liquid mainly containing phosphoric acid. Thus, as shown in FIG. 12, the insulating film 31 can be selectively formed on the first region 111 of the semiconductor substrate 10, and the insulating film 32 can be selectively formed on the third region 113.

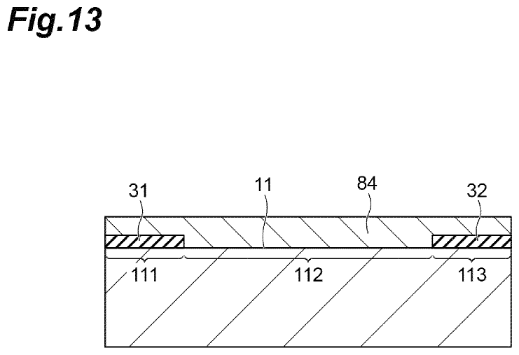

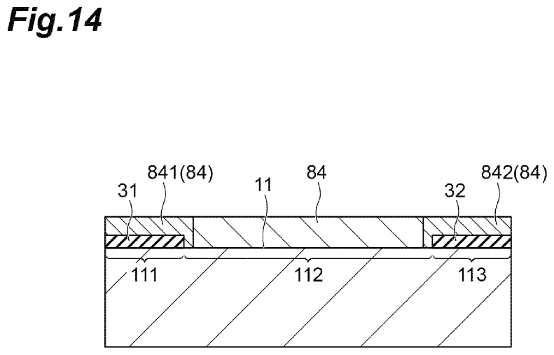

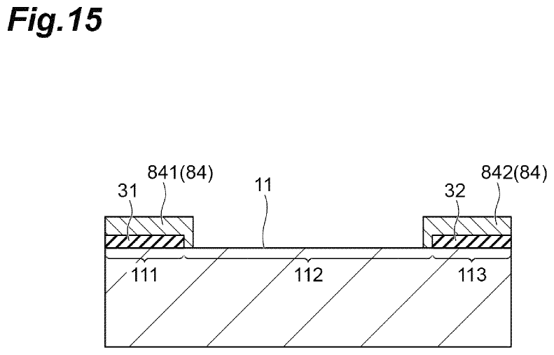

Subsequently, in processes shown in FIGS. 13 to 17, the conductive film 21 is formed on the second region 112 by using a lift-off method. First, as shown in FIG. 13, a resist 84 is applied to the entire main surface 11. In the following description, a case where the resist 84 is a negative type will be exemplified, but the resist 84 may be a positive type. Subsequently, as shown in FIG. 14, a portion on the first region 111 and a portion on the third region 113 in the resist 84 are exposed to form photosensitive portions 841, 842. Then, as shown in FIG. 15, a portion of the resist 84 other than the photosensitive portions 841, 842, that is, a portion on the second region 112 is removed by development.

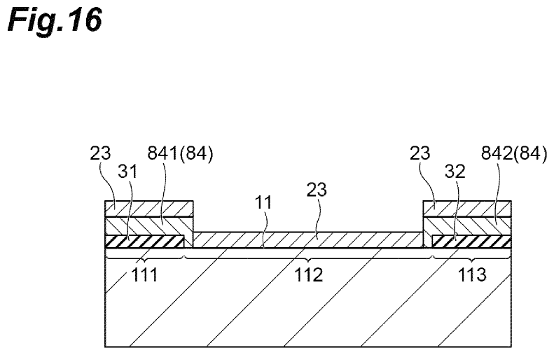

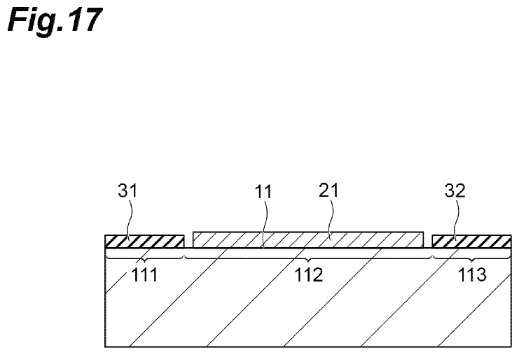

Subsequently, as shown in FIG. 16, a film 23 made of the material of the conductive film 21 is deposited on the entire surface of the main surface 11 by vapor deposition, for example. At this time, the film 23 is deposited on the second region 112 exposed from the resist 84 and on the resist 84 in the first region 111 and the third region 113. In one embodiment, the Ti film is formed first and then the Au film is formed. Alternatively, the Ti film may be formed first, the Pt film may be formed next, and then the Au film may be formed. Thereafter, as shown in FIG. 17, by peeling and removing the resist 84, only the film 23 on the second region 112, that is, the conductive film 21 remains.

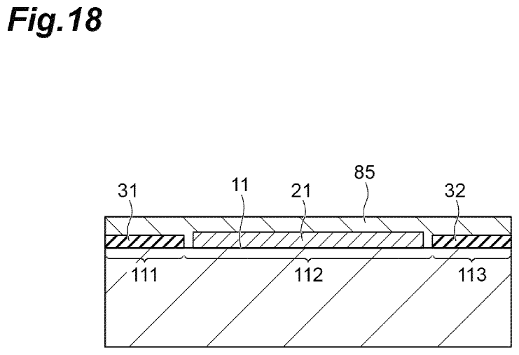

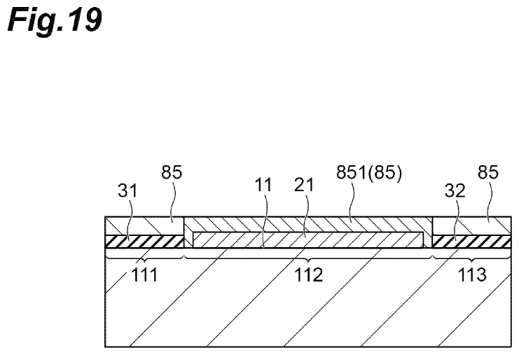

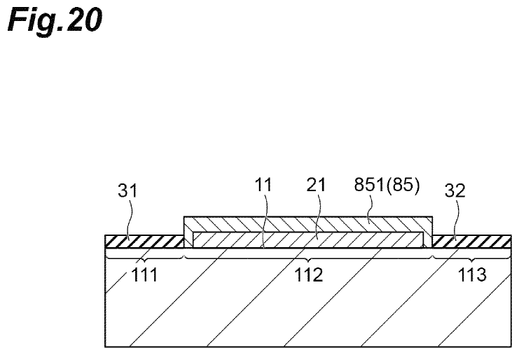

Subsequently, in the processes shown in FIGS. 18 to 22, metal pads 41, 42 are formed on the insulating films 31, 32, respectively, by a lift-off method. First, as shown in FIG. 18, a resist 85 is applied to the entire main surface 11. In the following description, a case where the resist 85 is a negative type will be exemplified, but the resist 85 may be a positive type. Subsequently, as shown in FIG. 19, a portion of the resist 85 on the conductive film 21 is exposed to form a photosensitive portion 851. Then, as shown in FIG. 20, portions of the resist 85 other than the photosensitive portion 851, that is, a portion on the insulating film 31 and a portion on the insulating film 32 are removed by development.

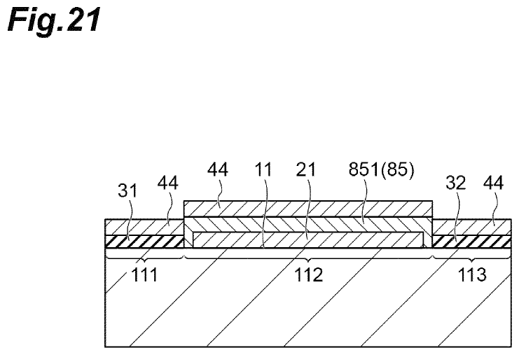

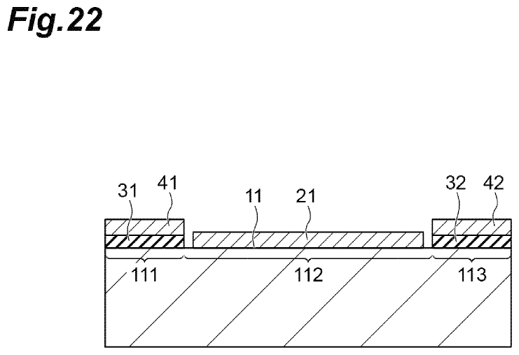

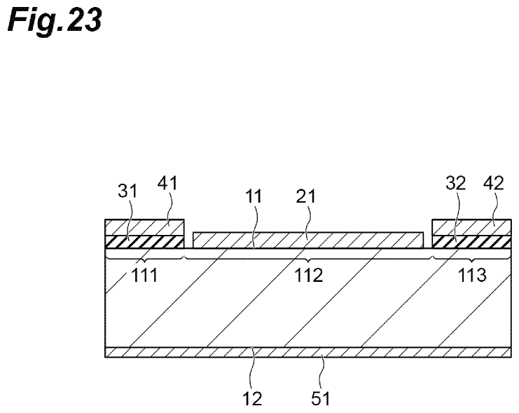

Subsequently, as shown in FIG. 21, a film 44 made of the material of the metal pads 41, 42 is deposited on the entire surface of the main surface 11 by vapor deposition, for example. At this time, the film 44 is deposited on the insulating films 31, 32 exposed from the resist 85 and on the photosensitive portion 851 of the resist 85. Thereafter, as shown in FIG. 22, by peeling and removing the resist 85, only the film 44 on the insulating films 31, 32, that is, the metal pads 41, 42 remains. Thereafter, as shown in FIG. 23, a back surface metal film 51 is formed on the back surface 12 of the semiconductor substrate 10 by, for example, vapor deposition. Through the above processes, the capacitor 1 of the present embodiment is manufactured.

An operation and an effect obtained by the capacitor 1 of the present embodiment having the above-described configuration will be described below together with a problem of a conventional capacitor.

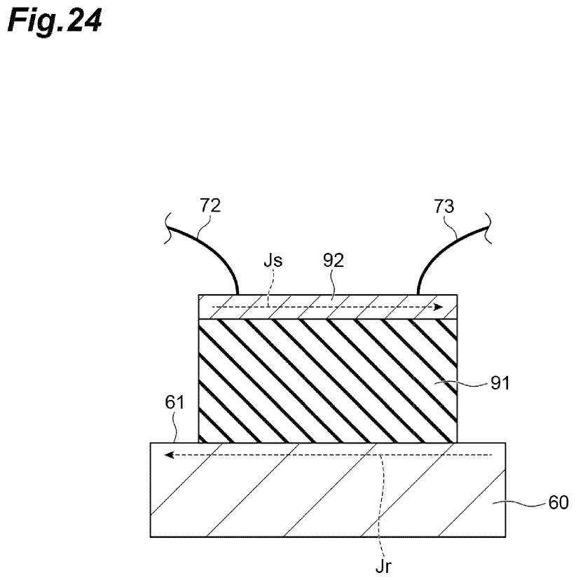

For example, in the case of an electronic device that inputs and outputs a high-frequency signal having a frequency equal to or higher than 100 MHz, a capacitor is used to match an input impedance and an output impedance of a semiconductor element incorporated in the electronic device. As an example, as shown in FIG. 24, a member having a ceramic substrate 91 and a metal pad 92 provided on the ceramic substrate 91 is disposed on a conductive base 60. Thus, capacitance can be obtained between the metal pad 92 and the base 60. In this case, the base 60 is defined at a constant potential, for example, a common ground potential with the semiconductor element. The metal pad 92 is connected by the wire 72 to a signal input terminal or a signal output terminal of the semiconductor element, and is connected by the wire 73 to a signal input terminal or a signal output terminal of a housing that houses the semiconductor element. When the signal current Js propagates through the metal pad 92, a return current Jr flows through the base 60.

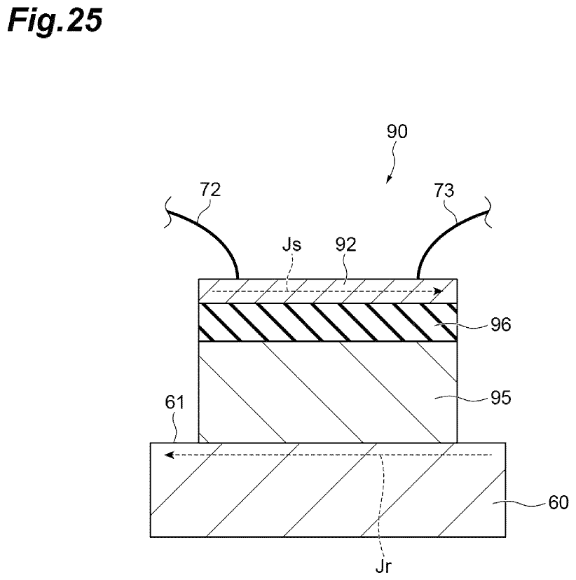

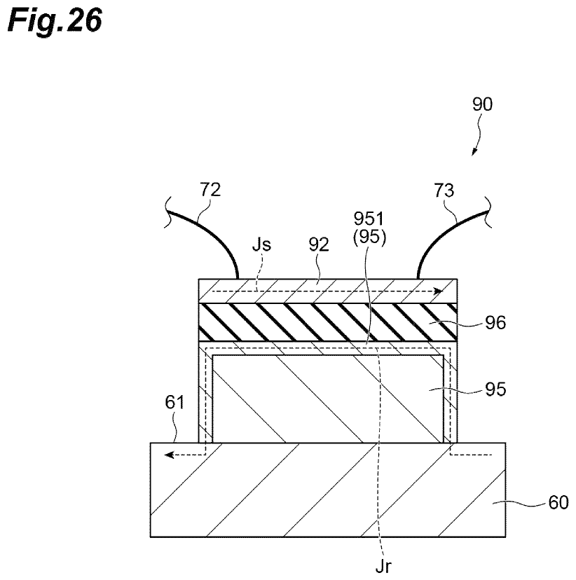

Here, as shown in FIG. 25, it is considered that a semiconductor substrate 95 on which an insulating film 96 is formed is used instead of the ceramic substrate 91 of FIG. 24. For example, a capacitor in which a silicon oxide film is formed on a silicon substrate and a metal pad is provided thereon is called a MOS capacitor. When the capacitor 90 having the insulating film 96 on the semiconductor substrate 95 and further having the metal pad 92 thereon is used in an electronic device for high-frequency, the following problem occurs. When the signal frequency is relatively low, the return current Jr mainly flows in the base 60 and hardly flows in the semiconductor substrate 95. On the other hand, when the signal frequency is relatively high, for example, equal to or higher than the 100 MHZ, as shown in FIG. 26, the return current Jr mainly flows through a region 951 near the upper surface of the semiconductor substrate 95 due to the so-called skin effect.

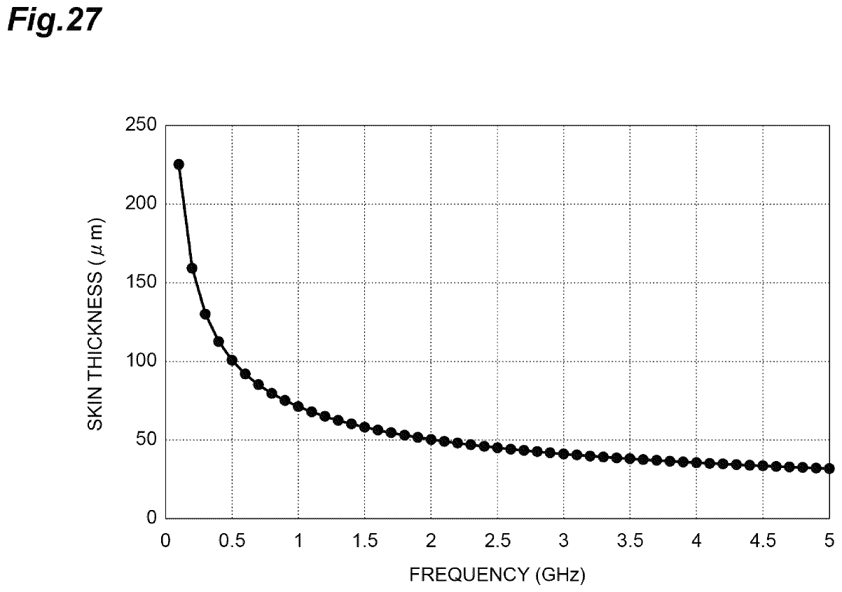

FIG. 27 is a graph showing the relationship between the thickness of the region 951, the so-called skin thickness, and the signal frequency when the semiconductor substrate 95 is made of silicon. The electrical resistivity of silicon is 2.0×10⁻⁵ Ω·m. In FIG. 27, the vertical axis represents skin thickness (μm), and the horizontal axis represents frequency (GHz). As is clear from FIG. 27, the skin thickness becomes smaller as the signal frequency become higher, and becomes smaller than 100 μm when the signal frequency exceed the 700 MHZ. Since it is desirable that the semiconductor substrate 95 has a thickness of 100 μm or more in order to reduce cracks, the region 951 by the skin effect is biased to the vicinity of the upper surface of the semiconductor substrate 95.

When the return current Jr flows through the inside of the semiconductor substrate 95, the return current Jr is affected by the electrical resistance of the semiconductor substrate 95 and the high-frequency signal is attenuated.

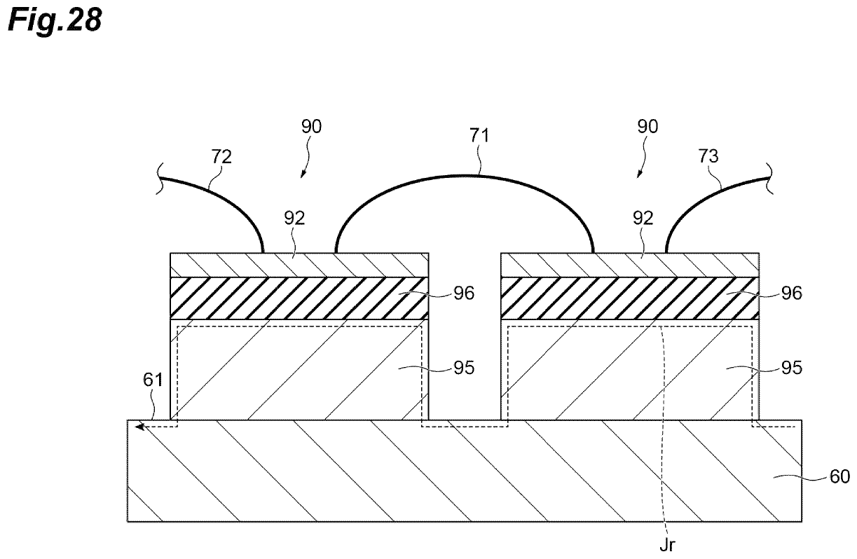

FIG. 28 is a diagram showing an example in which two capacitors 90 having the configuration shown in FIG. 25 are arranged in series. In this case, the metal pad 92 of one capacitor 90 is connected to the signal input terminal or the signal output terminal of the semiconductor element by the wire 72. The metal pad 92 of the other capacitor 90 is connected to a signal input terminal or a signal output terminal of a housing that houses the semiconductor element by the wire 73. The metal pad 92 of one capacitor 90 and the metal pad 92 of the other capacitor 90 are connected to each other by the wire 71. According to such a configuration, an internal matching circuit is configured by combining the capacitance of the two capacitors 90 and the inductances of the three wires 71, 72 and 73, and the matching of the input impedance or the output impedance of the semiconductor element is further improved. Also in such a configuration, the return current Jr flows near the upper surface of the semiconductor substrate 95 of each capacitor 90 due to the skin effect.

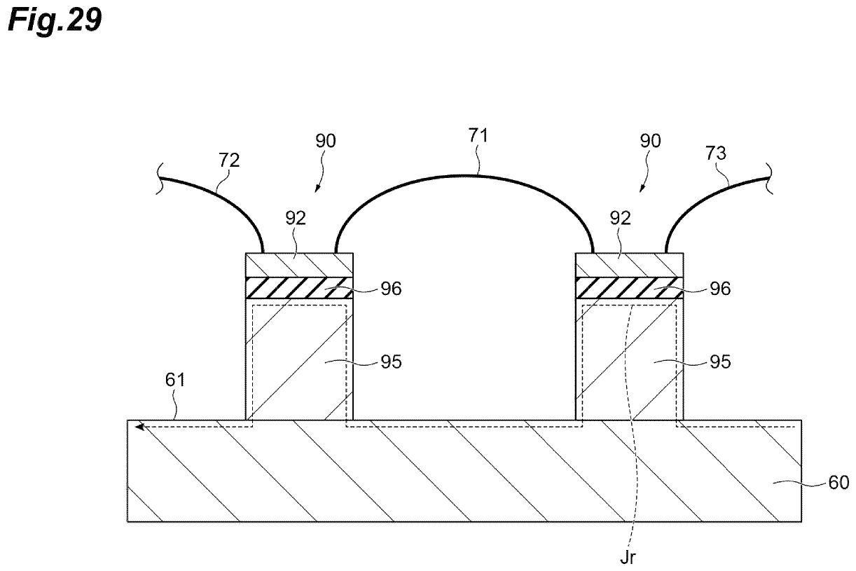

In order to reduce the attenuation of the high-frequency signal due to the skin effect, as shown in FIG. 29, it is effective to make the thickness of the insulating film 96 thin and make the width of the semiconductor substrate 95 in the traveling direction of the return current Jr as small as possible. Thus, it is possible to shorten the path of the return current Jr in the semiconductor substrate 95 while securing the necessary capacitance of each capacitor 90. However, as the width of the semiconductor substrate 95 is made smaller, handling of the capacitor 90 becomes more difficult. That is, cracks tend to occur in the semiconductor substrate 95, and a rotation error occurs in the capacitor 90 when the electronic device is assembled.

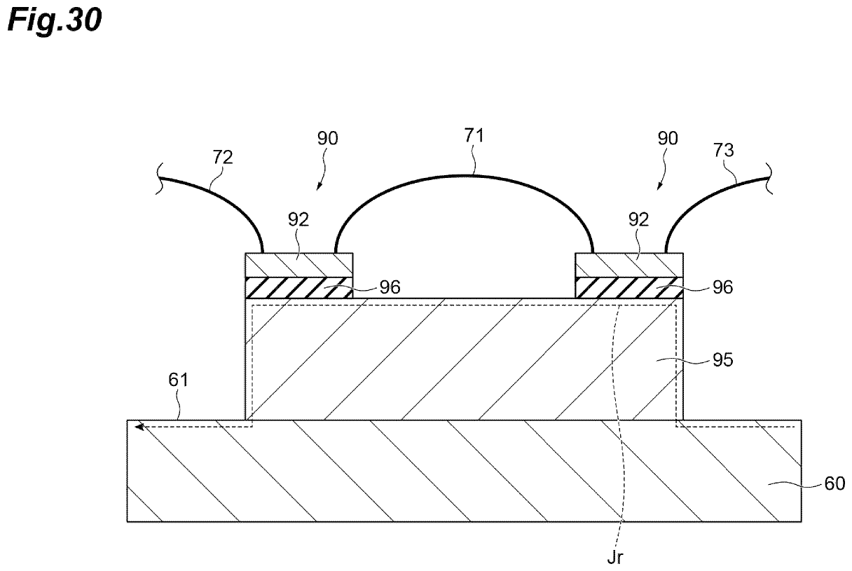

As shown in FIG. 30, when the semiconductor substrates 95 of the two capacitors 90 are made common while maintaining the relationship between the two metal pads 92 and the three wires 71, 72 and 73, problems such as the occurrence of cracks and the difficulty in handling the capacitors 90 are solved, but the problem of attenuation of the high-frequency signal due to the skin effect still remains.

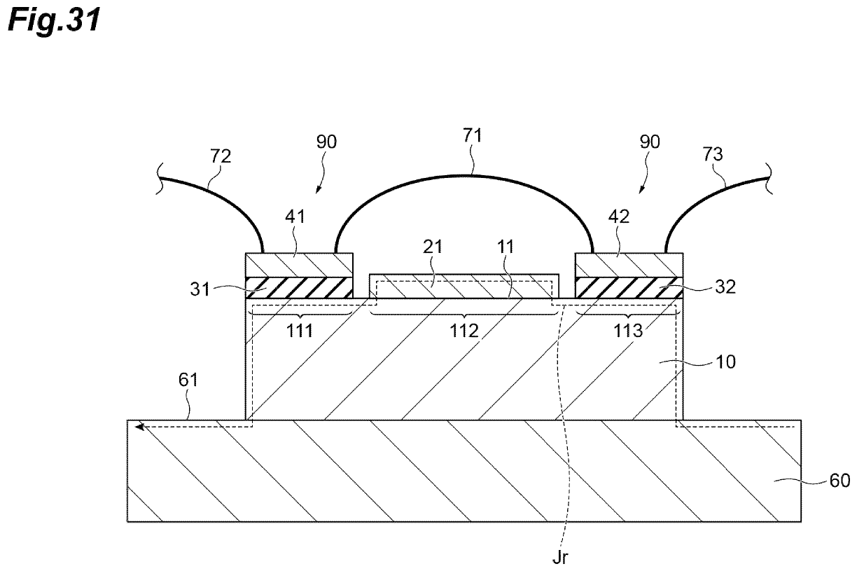

In order to solve the above-described problem, in the capacitor 1 of the present embodiment, the conductive film 21 is provided on the main surface 11 of the semiconductor substrate 10 in addition to the insulating films 31, 32 and the metal pads 41, 42 for obtaining capacitance. The conductive film 21 is provided side by side with the insulating films 31, 32 and the metal pads 41, 42, and is in ohmic contact with the main surface 11 of the semiconductor substrate 10. Therefore, as shown in FIG. 31, the high-frequency return current Jr mainly flows in the vicinity of the main surface 11 of the semiconductor substrate 10 in the first region 111 and the third region 113, but mainly flows in the conductive film 21, that is in ohmic contact with the main surface 11 of the semiconductor substrate 10, in the second region 112. Accordingly, it is possible to shorten the path of the return current Jr in the semiconductor substrate 10 while securing the sufficient width Wa of the semiconductor substrate 10 and solving problems such as the occurrence of cracks and the difficulty in handling the capacitor 90. Therefore, according to the capacitor 1 of the present embodiment, it is possible to suppress attenuation of a high-frequency signal.

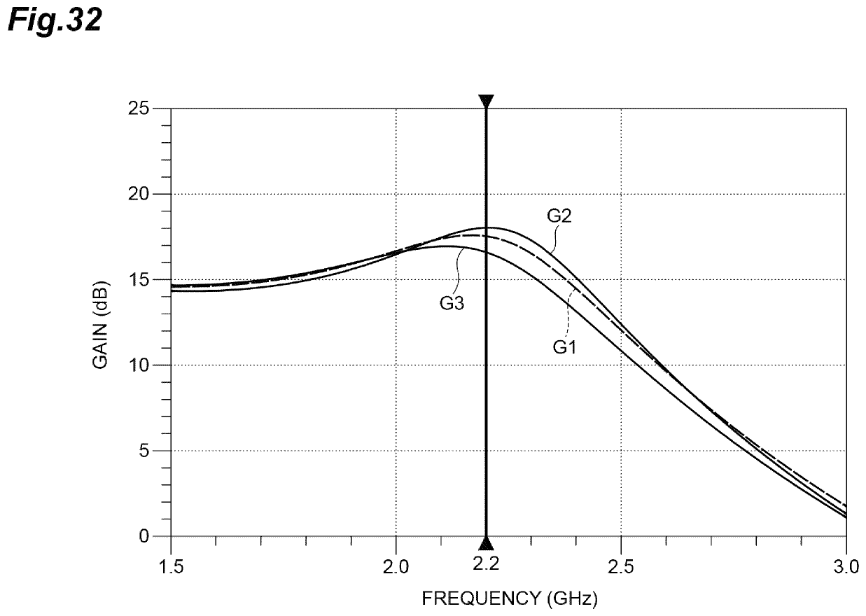

A curve G1 in FIG. 32 indicates a S21 transmission characteristic of a case A in which the capacitor 1 of the present embodiment is applied to an input matching circuit of an RF-amplifier using a transistor as a semiconductor element. In FIG. 32, a curve G2 and a curve G3 are shown together for comparison. The curve G2 indicates the S21 transmission characteristics of the case B in which the ceramic substrate 91 is used instead of the semiconductor substrate (see FIG. 24). The curve G3 indicates the S21 transmission characteristics of the case C in which the conductive film 21 is not provided on the semiconductor substrate (see FIG. 30). In FIG. 32, the vertical axis represents the Gain (dB) and the horizontal axis represents the signal frequency (GHz). Table 1 below shows the maximum values of the Gain at 2.2 GHz in these cases A, B, and C.

TABLE 1

| capacitor structure | Gain (dB) |
|---|---|
| case A | 17.5 |
| case B | 18.0 |
| case C | 16.6 |

As shown in FIG. 32 and Table 1, according to the capacitor 1 of this embodiment, the attenuation of the Gain of the RF amplifier is greater than that in the case where the ceramic substrate 91 is used, but the attenuation of the Gain of the RF amplifier can be lower than that in the case where the conductive film 21 is not provided on the semiconductor substrate.

As in the present embodiment, the capacitor 1 may include the insulating film 32 and the metal pad 42 provided on the third region 113 in addition to the insulating film 31 and the metal pad 41 provided on the first region 111. The conductive film 21 on the second region 112 may be located between the pair of the insulating film 31 and the metal pad 41 and the pair of the insulating film 32 and the metal pad 42. In this case, by connecting the metal pad 41 and the metal pad 42 by the wire 71, a matching circuit having two stages of capacitor portions and inductance therebetween can be realized by a single capacitor element.

As described above, the width Wd of the conductive film 21 in the direction D1 may be larger than the width Wc of the metal pads 41, 42 in the same direction. By reducing the width Wc of the metal pad 41 and increasing the width Wd of the conductive film 21 in this manner, the portion of the path of the return current Jr in the semiconductor substrate 10 can be shortened and the portion thereof in the conductive film 21 can be lengthened. Therefore, it is possible to effectively reduce the attenuation of the high-frequency signal while securing the sufficient width Wa of the semiconductor substrate 10.

As in the present embodiment, the conductive film 21 may be made of metal. In this case, the conductive film 21 having an electrical resistivity lower than an electrical resistivity of the semiconductor substrate 10 can be easily formed.

When the semiconductor substrate 10 is a silicon substrate, as shown in FIG. 3, the conductive film 21 may include a Ti film 211 in contact with the silicon substrate and an Au film 212 provided on the Ti film 211. In this case, the semiconductor substrate 10 and the conductive film 21 are firmly bonded to each other, and the reliability of the capacitor 1 can be improved. As shown in FIG. 4, the Pt film 213 may be provided between the Ti film 211 and the Au film 212.

As in the present embodiment, the capacitor 1 may include a back surface metal film 51 provided on the back surface 12 of the semiconductor substrate 10 and in contact with the semiconductor substrate 10. In this case, the back surface metal film 51 and the base 60 can be easily and firmly conductive-bonded by using the conductive paste 74 or the like.

As described above, the electrical resistivity of the semiconductor substrate 10 may be 1.0×10⁻⁴ Ω·cm or more and 1 Ω·cm or less. The capacitor 1 of the present embodiment is particularly effective when the semiconductor substrate 10 having such electrical resistivity, typically a silicon substrate, is used.

As in the present embodiment, the metal pads 41, 42 extend along the direction D2, and the length Lc of the metal pads 41, 42 in the direction D2 may be greater than the width Wc of the metal pads 41, 42 in the direction D1. As described above, since the metal pad 41 has a long planar shape in the direction D1 intersecting the direction D2 which is the current traveling direction, the current densities of the signal current Js and the return current Jr are suppressed, and thus the capacitor 1 can be used in an electronic device for high power.

The method of manufacturing the capacitor 1 described above includes a process of forming the SiN mask 83, a process of forming the silicon oxide film, a process of forming the conductive film 21, and a process of forming the metal pads 41, 42. In the process of forming the SiN mask 83, the SiN mask 83 having openings 831, 832 in the first region 111 and the third region 113 is formed on the main surface 11 of the silicon substrate as the semiconductor substrate 10. In the process of forming the silicon oxide film, the silicon oxide films as the insulating films 31, 32 are formed in the first region 111 and the third region 113 of the main surface 11. In the process of forming the conductive film 21, the SiN mask 83 is removed, and then the conductive film 21 is formed so as to be in ohmic contact with the main surface 11 of the semiconductor substrate 10. In the process of forming the conductive film 21, the conductive film 21 is formed on the second region 112 of the main surface 11 of the semiconductor substrate 10 using the lift-off method. In the process of forming the metal pads 41, 42, the metal pads 41, 42 for wire bonding are formed on the silicon oxide film by the lift-off method.

When a silicon substrate is used as the semiconductor substrate 10, the silicon oxide film can be easily formed by thermal oxidation of the surface of the silicon substrate. In this case, the silicon oxide film can be formed on the surface of the silicon substrate by placing the silicon substrate in an oxygen atmosphere and heating the silicon substrate to a temperature in the range of 700° C. to 1100° C. At this time, in order to avoid melting of the conductive film 21 due to heating, it is desirable to thermally oxidize the surface of the silicon substrate at a stage where the conductive film 21 is not formed on the silicon substrate. Therefore, in the present embodiment, an SiN mask 83 is formed as an oxidation prevention mask, and the silicon oxide film is selectively formed using the SiN mask 83 in a region where a capacitor is to be formed. According to this method, the capacitor 1 of the present embodiment can be easily manufactured.

### (First Modification)

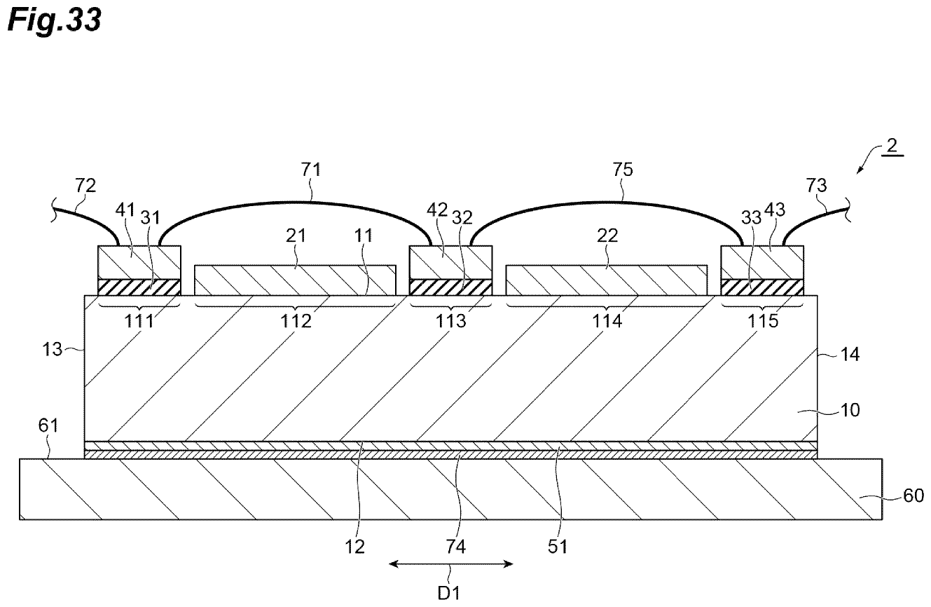

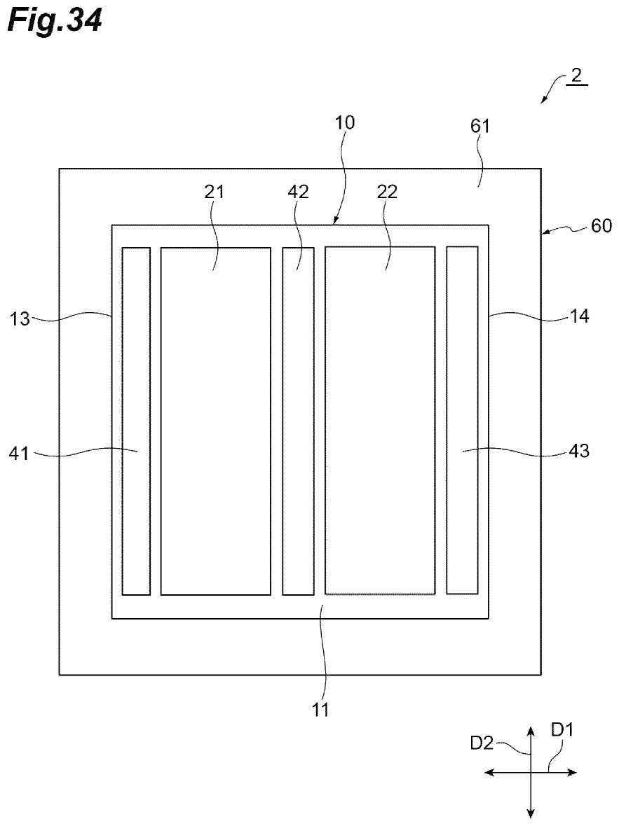

FIG. 33 is a cross-sectional view showing the structure of a capacitor 2 as a passive element according to a first modification of the above embodiment. FIG. 34 is a plan view of the capacitor 2. The capacitor 2 of this modification is different from the capacitor 1 of the above-described embodiment in the following points, and is the same in other points.

The main surface 11 of the semiconductor substrate 10 of the capacitor 2 further includes a fourth region 114 and a fifth region 115 in addition to the first region 111, the second region 112, and the third region 113. The first region 111, the second region 112, the third region 113, the fourth region 114, and the fifth region 115 are arranged in this order along the direction D1. That is, the fourth region 114 is disposed between the third region 113 and the fifth region 115. The capacitor 2 further includes a conductive film 22 (second conductive film), an insulating film 33 (third insulating film), and a metal pad 43 (third metal pad).

The conductive film 22 is provided on the fourth region 114 in the main surface 11 of the semiconductor substrate 10. The conductive film 22 is in ohmic contact with the main surface 11 of the semiconductor substrate 10, and has an electrical resistivity lower than an electrical resistivity of the semiconductor substrate 10. The planar shape of the conductive film 22 may be the same as the planar shape of the conductive film 21. The constituent material of the conductive film 22 is selected from, for example, those exemplified as the constituent material of the conductive film 21. In one embodiment, the material of the conductive film 22 is the same as that of the conductive film 21. The thickness, the width in the direction D1, and the length in the direction D2 of the conductive film 22 are included in the numerical ranges exemplified for the thickness Td, the width Wd, and the length Ld of the conductive film 21, respectively. In one embodiment, the thickness, the width in the direction D1, and the length in the direction D2 of the conductive film 22 are equal to the thickness Td, the width Wd, and the length Ld of the conductive film 21, respectively.

The insulating film 33 is provided on the fifth region 115 in the main surface 11 of the semiconductor substrate 10. The planar shape of the insulating film 33 may be the same as each planar shape of the insulating films 31, 32. The constituent material of the insulating film 33 is selected from, for example, those exemplified as the constituent material of the insulating films 31, 32. In one embodiment, the material of the insulating film 33 is the same as the material of the insulating films 31, 32. The thickness of the insulating film 33 is included in the numerical range exemplified for the thickness Tb of the insulating films 31, 32, for example. In one embodiment, the thickness of the insulating film 33 is equal to the thickness Tb of the insulating films 31, 32.

The metal pad 43 is a metal pad for wire bonding and is provided on the insulating film 33. The planar shape of the metal pad 43 may be the same as the planar shape of the metal pads 41, 42. The constituent material of the metal pad 43 is selected from, for example, those exemplified as the constituent material of the metal pads 41, 42. In one embodiment, the material of metal pad 43 is the same as the material of metal pads 41, 42. For example, the thickness, the width in the direction D1, and the length in the direction D2 of the metal pad 43 are included in the numerical ranges exemplified for the thickness Tc, the width Wc, and the length Lc of the metal pads 41, 42, respectively. In one embodiment, the thickness, the width in the direction D1, and the length in the direction D2 of the metal pad 43 are equal to the thickness Tc, the width Wc, and the length Lc of the metal pads 41, 42, respectively.

Instead of the wire 73, one end of a conductive wire 75 is bonded to the metal pad 42. The other end of the wire 75 is bonded to the metal pad 43. Thus, the metal pad 42 and the metal pad 43 are electrically connected by the wire 75. One end of a wire 73 is bonded to the metal pad 43. The other end of the wire 73 is bonded to, for example, a signal input terminal or a signal output terminal of a housing (not shown). Accordingly, the metal pad 43 is electrically connected to the signal input terminal or the signal output terminal of the housing by the wire 73.

According to this modification, attenuation of the high-frequency signal can be reduced as in the above-described embodiment. In addition, according to this modification, a matching circuit having three stages of capacitor portions and inductances therebetween can be realized by a single capacitor element.

### (Second Modification)

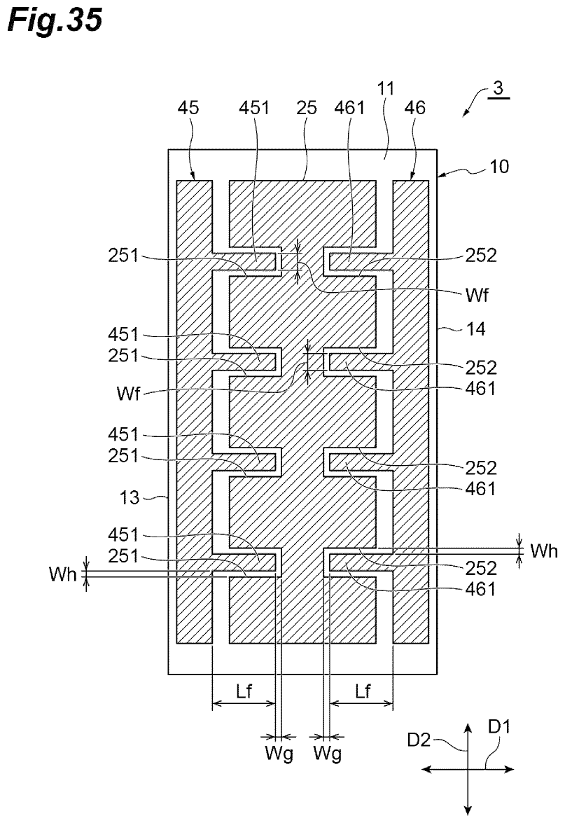

FIG. 35 is a plan view showing a capacitor 3 as a passive element according to a second modification of the above embodiment. The capacitor 3 of this modified example is different from the capacitor 1 of the above-described embodiment in the following points, and is the same in other points.

The capacitor 3 includes a metal pad 45 instead of the metal pad 41 of the above-described embodiment. The capacitor 3 includes a metal pad 46 instead of the metal pad 42 of the above-described embodiment. The capacitor 3 includes a conductive film 25 instead of the conductive film 21 of the above-described embodiment. The arrangement and constituent material of the metal pads 45 and 46 and the conductive film 25 are the same as those of the metal pads 41 and 42 and the conductive film 21 of the above-described embodiment. In the drawing, the metal pads 45 and 46 and the conductive film 25 are hatched for easy understanding.

The metal pad 45 has one or a plurality of protrusions 451 (first protrusions) protruding toward the metal pad 46 from a side facing the metal pad 46. Four protrusions 451 are illustrated in the drawing. The conductive film 25 has the same number of indentations 251 (first indentations) as the protrusions 451, each of which surround each protrusion 451 from three sides, on a side facing the metal pad 45. The metal pad 46 includes one or a plurality of protrusions 461 (second protrusions) protruding toward the protrusions 451 from a side facing the metal pad 45. Four protrusions 461 are illustrated in the drawing. The conductive film 25 has the same number of indentations 252 (second indentations) as the protrusions 461, each of which surround each protrusion 461 from three sides, on a side facing the metal pad 46. The widths Wf of the protrusions 451, 461 in the direction D2 are, for example, 40 μm or more and 100 μm or less. The protrusion lengths Lf of the protrusions 451, 461 in the direction D1 is, for example, 500 μm. The widths Wg of the gaps between the protrusions 451, 461 and the indentations 251, 252 in the direction D1 are, for example, 5 μm or more and 200 μm or less. The widths Wh of the gaps between the protrusions 451, 461 and the indentations 251, 252 in the direction D2 are, for example, 5 μm or more and 50 μm or less.

In this modification, the planar shapes of the insulating film 31 and the first region 111 (see FIG. 1) coincide with the planar shape of the metal pad 45. The planar shapes of the insulating film 32 and the third region 113 (see FIG. 1) coincide with the planar shape of the metal pad 46. The planar shape of the second region 112 (see FIG. 1) coincides with the planar shape of the conductive film 25.

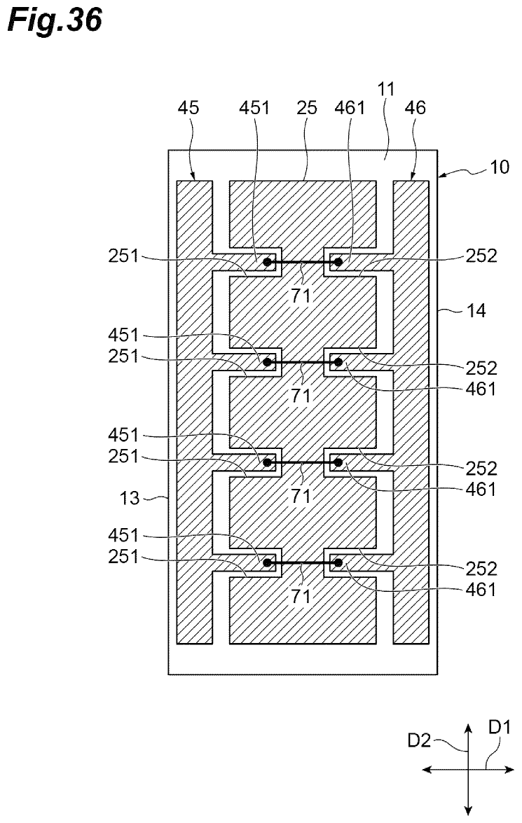

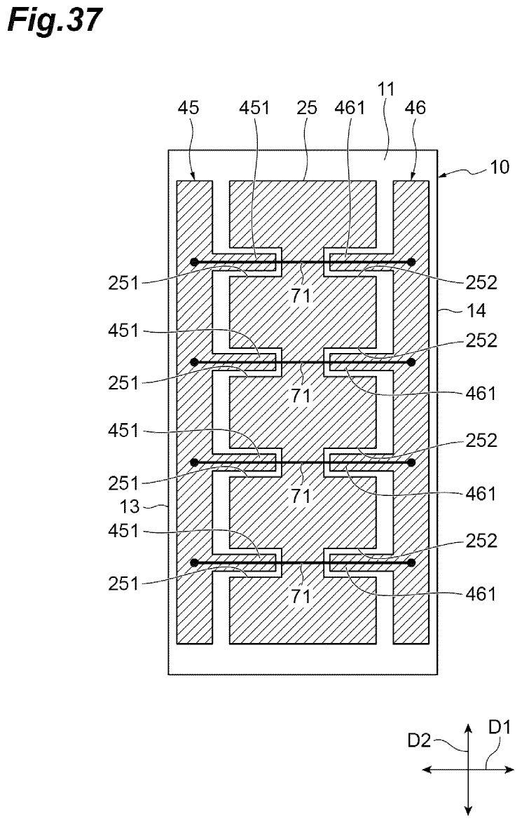

FIGS. 36 and 37 are plan views showing a state in which wires 71 are connected to the metal pads 45 and 46. FIG. 36 shows a case where one end of the wire 71 is bonded to the vicinity of the tip of the protrusion 451, and the other end of the wire 71 is bonded to the vicinity of the tip of the protrusion 461. In this case, the lengths of the wires 71 can be shortened. FIG. 37 shows a case where one end of the wire 71 is bonded to the vicinity of the base end of the protrusion 451 and the other end of the wire 71 is bonded to the vicinity of the base end of the protrusion 461. In this case, the length of the wire 71 can be made longer. As described above, according to the present modification, it is possible to bond the ends of the wire 71 connecting the metal pad 45 and the metal pad 46 to the protrusions 451, 461, and the adjustable range of the length of the wire 71 is expanded. The width of the first region 111 in the traveling direction of the return current Jr (see FIG. 31) can be kept narrow in the portion of the first region 111 other than the portion immediately below the protrusion 451. This makes it possible to keep the width of the second region 112, that is, the width Wd of the conductive film 25 wide. Furthermore, the width of the third region 113 in the traveling direction of the return current Jr can be kept narrow in the portion of the third region 113 other than the portion immediately below the protrusion 461. This makes it possible to keep the width of the second region 112, that is, the width Wd of the conductive film 25 wider. Therefore, it is possible to effectively reduce the attenuation of the high-frequency signal while increasing the degree of freedom of the lengths of the wires 71, that is, the magnitude of the inductance.

In this modification, only one of the protrusion 451 of the metal pad 45 and the protrusion 461 of the metal pad 46 may be provided. That is, the metal pad 45 (or the metal pad 46) of the present modification and the metal pad 42 (or the metal pad 41) of the above-described embodiment may be combined with each other. In this case, only one of the indentations 251 and 252 is provided also in the conductive film 25.

### (Third Modification)

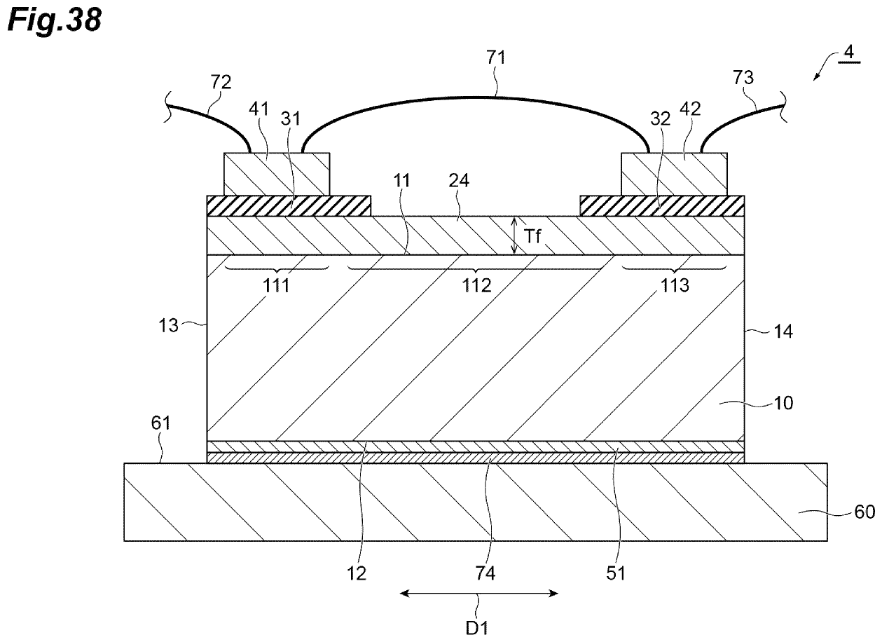

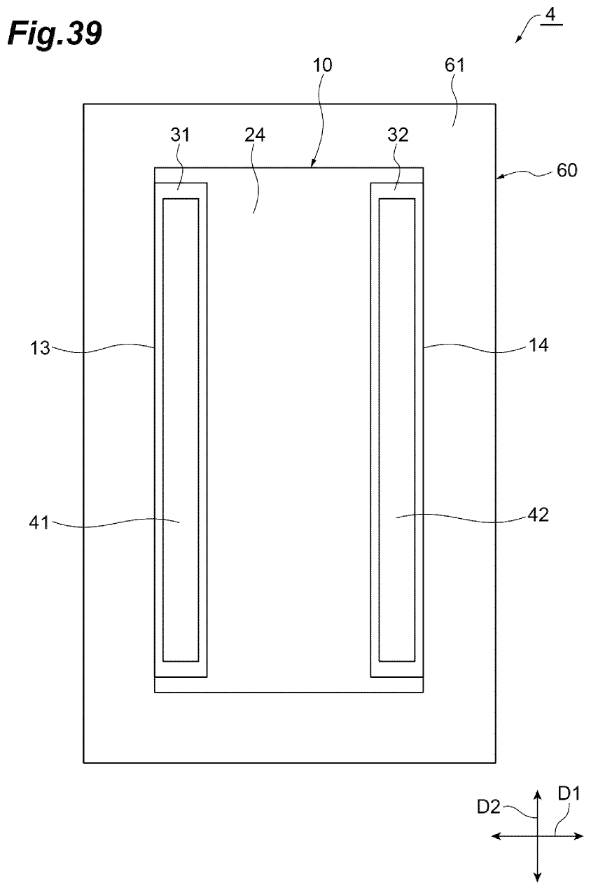

FIG. 38 is a cross-sectional view showing the structure of a capacitor 4 as a passive element according to a third modification of the above embodiment. FIG. 39 is a plan view of the capacitor 4. The capacitor 4 of the present modification is different from the capacitor 1 of the above-described embodiment in the following points, and is the same in other points.

The capacitor 4 includes a conductive film 24 instead of the conductive film 21 of the above-described embodiment. The conductive film 24 is provided on a region including the first region 111, the second region 112, and the third region 113 in the main surface 11 of the semiconductor substrate 10. In the illustrated example, the conductive film 24 is provided on the entire main surface 11 of the semiconductor substrate 10. The conductive film 24 is in ohmic contact with the main surface 11 of the semiconductor substrate 10. The conductive film 24 has an electrical resistivity lower than an electrical resistivity of the semiconductor substrate 10. The constituent material of the conductive film 24 is selected from, for example, those exemplified as the constituent material of the conductive film 21. The thickness of the conductive film 24 is included in the numerical range exemplified for the thickness Td of the conductive film 21, for example.

In the present modification, the insulating film 31 is provided on the first region 111 and on the conductive film 24. The insulating film 32 is provided on the third region 113 and on the conductive film 24. An upper surface of a portion of the conductive film 24 on the second region 112 is exposed from the insulating films 31 and 32.

When the capacitor 4 of the present modification is mounted on the conductive base 60, the conductive film 24 is electrically connected to the base 60 via the semiconductor substrate 10 and has the same potential as the base 60. Therefore, capacitance is obtained between the conductive film 24 and the metal pads 41, 42. This capacitance depends on the area of the metal pads 41, 42 and the distance from the metal pads 41, 42 to the conductive film 24, typically the thickness of the insulating films 31, 32. Therefore, when the metal pads 41, 42 are connected to the signal terminal of the semiconductor element by the wires 71, 72, the input impedance or the output impedance at the signal terminal can be matched.

In this modification, the conductive film 24 in contact with the main surface 11 of the semiconductor substrate 10 is provided from the first region 111 to the third region 113 via the second region 112. Therefore, the high-frequency return current Jr (see FIG. 31) mainly flows in the conductive film 24 in any of the first region 111, the second region 112, and the third region 113. As a result, it is possible to shorten the path of the return current Jr in the semiconductor substrate 10 while sufficient width Wa (see FIG. 2) of the semiconductor substrate 10. Therefore, according to the present modification, it is possible to suppress attenuation of the high-frequency signal.

As in the present modification, the capacitor 4 may include the insulating film 32 and the metal pad 42 provided on the third region 113 in addition to the insulating film 31 and the metal pad 41 provided on the first region 111. Then, the second region 112 may be located between the first region 111 and the third region 113. In this case, by connecting the metal pad 41 and the metal pad 42 by the wire 71, a matching circuit having two stages of capacitor portions and inductance therebetween can be realized by a single capacitor element.

### Second Embodiment

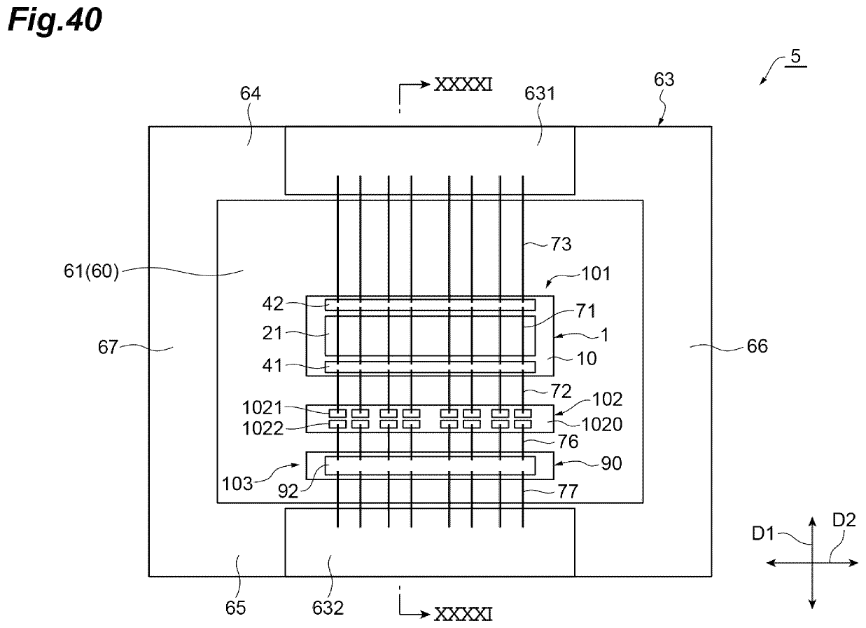

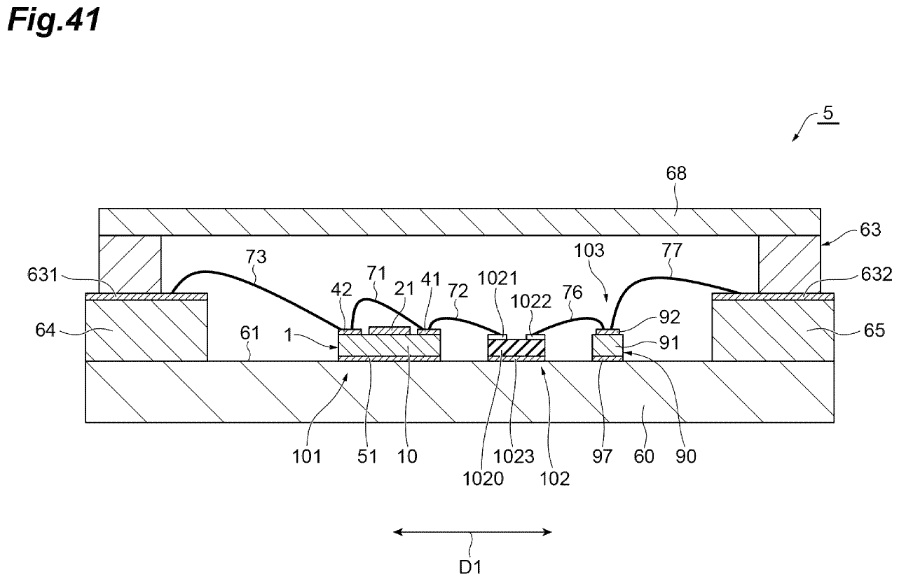

FIG. 40 is a plan view showing the configuration of the electronic device 5 according to the second embodiment. FIG. 41 is a cross-sectional view taken along line XXXXI-XXXXI of FIG. 40. The electronic device 5 according to the present embodiment receives a high-frequency signal having a fundamental frequency equal to or higher than 100 MHz, amplifies the high-frequency signal, and outputs the amplified high-frequency signal.” The electronic device 5 includes a housing 63, an input matching circuit 101, a transistor element 102, and an output matching circuit 103. The housing 63 includes a base 60, end walls 64, 65, side walls 66, 67, and a lid 68 (see FIG. 41). The end walls 64, 65 and the side walls 66, 67 are made of an insulating material such as a multilayer ceramic material, and are provided on the base 60. The base 60 has a planar shape such as a substantially rectangular shape, and mounts thereon the input matching circuit 101, the transistor element 102, and the output matching circuit 103. The end walls 64, 65 are arranged in the direction D1 and extend along the direction D2. The side walls 66, 67 are arranged in the direction D2 and extend along the direction D1. The housing 63 further includes a signal input terminal 631 for inputting a high-frequency signal and a signal output terminal 632 for outputting an amplified high-frequency signal. The signal input terminal 631 is provided on the end wall 64, and the signal output terminal 632 is provided on the end wall 65.

The input matching circuit 101, the transistor element 102, and the output matching circuit 103 are arranged in this order in the direction D1. The input matching circuit 101, the transistor element 102, and the output matching circuit 103 are disposed between the end wall 64 and the end wall 65 in the direction D1 and are disposed between the side wall 66 and the side wall 67 in the direction D2. The input matching circuit 101, the transistor element 102, and the output matching circuit 103 are surrounded by end walls 64, 65 and side walls 66, 67. The lid 68 is disposed on the upper surfaces of the end walls 64, 65 and the side walls 66, 67, and airtightly seals a space accommodating the input matching circuit 101, the transistor element 102, and the output matching circuit 103. The lid 68 is made of, for example, ceramic or metal.

The transistor element 102 is an example of a semiconductor element in the present embodiment, and is, for example, a field effect transistor (FET). The transistor element 102 is disposed between the input matching circuit 101 and the output matching circuit 103 in the direction D1. The transistor element 102 includes, for example, a plurality of transistors for high-frequency amplification. The transistor element 102 includes a semiconductor substrate 1020, a plurality of signal input electrodes 1021 and a plurality of signal output electrodes 1022 that are signal electrodes, and a ground electrode 1023 (see FIG. 41). The plurality of signal input electrodes 1021 are arranged along the direction D2 at an edge close to the input matching circuit 101 on the main surface of the semiconductor substrate 1020. The plurality of signal output electrodes 1022 are arranged along the direction D2 at an edge close to the output matching circuit 103 on the main surface of the semiconductor substrate 1020. The ground electrode 1023 is provided on the back surface of the semiconductor substrate 1020. In one example, the signal input electrode 1021 is connected to control terminal (gate) of the transistor, the signal output electrode 1022 is connected to one current terminal (drain) of the transistor, and the ground electrode 1023 is connected to the other current terminal (source) of the transistor. The ground electrode 1023 is conductively bonded to the mounting surface 61 of the base 60 by a conductive paste (not shown).

The input matching circuit 101 includes the capacitor 1 of the first embodiment, a plurality of wires 71 (first wires), a plurality of wires 72 (second wires), and a plurality of wires 73. The metal pads 41 and 42 of the capacitor 1 are electrically connected to each other by the plurality of wires 71. The metal pad 41 of the capacitor 1 is electrically connected to the plurality of signal input electrodes 1021 of the transistor element 102 by the plurality of wires 72. The metal pad 42 of the capacitor 1 is electrically connected to the signal input terminal 631 of the housing 63 by the plurality of wires 73. The back surface metal film 51 of the capacitor 1 is conductively bonded to the mounting surface 61 of the base 60 by a conductive paste (not shown). The capacitances of the metal pads 41 and 42 and the inductances of the wires 71, 72, 73 match the input impedance of the transistor element 102. The input matching circuit 101 may include the capacitor 2 of the first modification, the capacitor 3 of the second modification, or the capacitor 4 of the third modification, instead of the capacitor 1 of the first embodiment.

The output matching circuit 103 includes the capacitor 90 shown in FIG. 25, a plurality of wires 76, and a plurality of wires 77. The metal pad 92 of the output matching circuit 103 is electrically connected to the signal output electrodes 1022 of the transistor element 102 by the plurality of wires 76 and is electrically connected to the signal output terminal 632 of the housing 63 by the plurality of wires 77. The back surface metal film 97 of the capacitor 90 is conductively bonded to the mounting surface 61 of the base 60 by a conductive paste (not shown). The capacitance of the metal pad 92 and the inductances of the wires 76, 77 match the output impedance of the transistor element 102. The output matching circuit 103 may include the ceramic capacitor illustrated in FIG. 24, the capacitor 1 of the first embodiment, the capacitor 2 of the first modification, the capacitor 3 of the second modification, or the capacitor 4 of the third modification instead of the capacitor 90.

According to the electronic device 5 of the present embodiment, since the input matching circuit 101 includes the capacitor 1 of the first embodiment, the capacitor 2 of the first modification, the capacitor 3 of the second modification, or the capacitor 4 of the third modification, attenuation of a high-frequency signal can be suppressed. In the case where the output matching circuit 103 includes the capacitor 1 of the first embodiment, the capacitor 2 of the first modification, the capacitor 3 of the second modification, or the capacitor 4 of the third modification, it is possible to further suppress the attenuation of the high-frequency signal.

### Third Embodiment

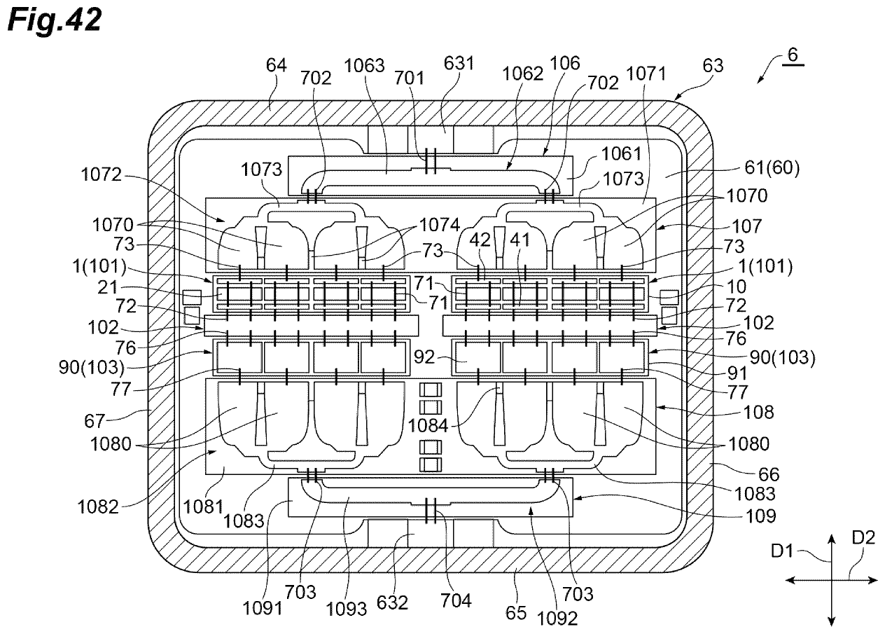

FIG. 42 is a plan view showing the configuration of the electronic device 6 according to the third embodiment. In FIG. 42, the lid of the package is not shown for ease of understanding. The electronic device 6 according to the present embodiment receives a high-frequency signal, amplifies the high-frequency signal, and outputs the amplified high-frequency signal. As shown in FIG. 42, the electronic device 6 includes a housing 63, two transistor elements 102, branch circuit boards 106 and 107, two input matching circuits 101, two output matching circuits 103, and multiplexing circuit boards 108 and 109. The configuration and arrangement of the housing 63, the input matching circuits 101, the transistor elements 102, and the output matching circuits 103 are the same as those in the second embodiment.

The branch circuit boards 106, 107 are arranged side by side in the direction D1, and are disposed between the signal input terminal 631 and the input matching circuit 101 in the direction D1. The branch circuit board 106 is located on the signal input terminal 631 side, and the branch circuit board 107 is located on the input matching circuit 101 side. The branch circuit board 106 includes a ceramic substrate 1061 and a branch circuit 1062 provided on a main surface of the substrate 1061. Similarly, the branch circuit board 107 includes a ceramic substrate 1071 and a branch circuit 1072 provided on a main surface of the substrate 1071. Metal films (not shown) are fixed to the back surfaces of the substrates 1061, 1071, and the metal films are bonded to the base 60 by metal pastes.

The branch circuits 1062 and 1072 are branch circuits for the input matching circuit 101. The branch circuit 1062 includes a wiring pattern 1063 provided on the main surface of the substrate 1061. The wiring pattern 1063 is electrically connected to the signal input terminal 631 by a wire 701. The wiring pattern 1063 branches in two directions from a connection point with the wire 701. The branch circuit 1072 includes two wiring patterns 1073 provided on the main surface of the substrate 1071. Each wiring pattern 1073 is electrically connected to each of two branched ends of the wiring pattern 1063 via a wire 702. Each wiring pattern 1073 repeats branching starting from the connection point with the wire 702, and finally reaches four metal pads 1070. The metal pads 1070 adjacent to each other are connected to each other via a film resistor 1074, and constitute a Wilkinson coupler. The metal pads 1070 are electrically connected to the metal pad 42 of the input matching circuit 101 by the wires 73.

The multiplexing circuit boards 108, 109 are arranged side by side in the direction D1, and are disposed between the output matching circuit 103 and the signal output terminal 632 in the direction D1. The multiplexing circuit board 108 is located on the output matching circuit 103 side, and the multiplexing circuit board 109 is located on the signal output terminal 632 side. The multiplexing circuit board 108 includes a ceramic substrate 1081 and a multiplexing circuit 1082 provided on a main surface of the substrate 1081. Similarly, the multiplexing circuit board 109 includes a ceramic substrate 1091 and a multiplexing circuit 1092 provided on a main surface of the substrate 1091. Metal films (not shown) are fixed to the back surface of the substrates 1081, 1091, and the metal films are bonded to the base 60 by metal pastes.

The multiplexing circuits 1082 and 1092 are multiplexing circuits for the output matching circuit 103. The multiplexing circuit 1082 includes two wiring patterns 1083 provided on the main surface of the substrate 1081. Each wiring pattern 1083 includes four metal pads 1080. The metal pads 1080 adjacent to each other are connected to each other via a film resistor 1084, and constitute a Wilkinson coupler. Each metal pad 1080 is electrically connected to the metal pad 92 of the output matching circuit 103 via the wires 77. Each wiring pattern 1083 repeats coupling from the four metal pads 1080 and finally reaches a connection point with the wire 703. Each wiring pattern 1083 is electrically connected to each of two end portions of the wiring pattern 1093 of the multiplexing circuit 1092 via a wire 703. A central portion of the wiring pattern 1093 is electrically connected to the signal output terminal 632 via a wire 704.

According to the electronic device 6 of the present embodiment, as in the second embodiment, the input matching circuit 101 includes the capacitor 1 of the first embodiment, the capacitor 2 of the first modification, the capacitor 3 of the second modification, or the capacitor 4 of the third modification, and thus it is possible to suppress attenuation of the high-frequency signal.

The passive element and the electronic device according to the present disclosure are not limited to the above-described embodiments, and various modifications are possible. For example, the above-described embodiments and modifications may be combined with each other in accordance with necessary purposes and effects. The third region 113, the insulating film 32, the metal pad 42, and the wire 71 may be omitted as necessary. In this case, one end of the wire 73 is bonded to the metal pad 41.

### REFERENCE SIGNS LIST

1, 2, 3, 4 capacitor (passive element)
5, 6 electronic device
10 semiconductor substrate
11 main surface
12 back surface
13, 14 side surface
21, 22, 21A, 21B, 24, 25 conductive film
23 film
31, 32, 33 insulating film
41, 42, 43, 45, 46 metal pad
44 film
51 back surface metal film
60 base
61 mounting surface
63 housing
64, 65 end wall
66, 67 side wall
68 lid
71, 72, 73, 75, 76, 77 wire
74 conductive paste
81 SiN film
82, 84, 85 resist
83 SiN mask
90 capacitor
91 ceramic substrate
92 metal pad
95 semiconductor substrate
96 insulating film
97 back surface metal film
101 input matching circuit
102 transistor element
103 output matching circuit
106, 107 branch circuit board
108, 109 multiplexing circuit board
111 first region
112 second region
113 third region
114 fourth region
115 fifth region
211 Ti film
212 Au film
213 Pt film
251, 252 indentation
451, 461 protrusion
631 signal input terminal
632 signal output terminal
701, 702, 703, 704 wire
821, 841, 842, 851 photosensitive portion
831, 832 opening
951 region
1020 semiconductor substrate
1021 signal input electrode
1022 signal output electrode
1023 ground electrode
1061, 1071, 1081, 1091 substrate
1062, 1072 branch circuit
1063, 1073 wiring pattern
1070, 1080 metal pad
1074, 1084 film resistor
1082, 1092 multiplexing circuit
1083, 1093 wiring pattern
D1, D2 direction
G1, G2, G3 curve
Ga gap
Jr return current
Js signal current

1. A passive element comprising:
a semiconductor substrate having a p-type or n-type conductivity and having a main surface and a back surface;
a back surface metal film provided on the back surface of the semiconductor substrate;
a first insulating film provided on the main surface of the semiconductor substrate;
a first metal pad provided on the first insulating film;
a first conductor extending from the first metal pad in a first direction; and
a first conductive film provided adjacent to the first metal pad in the first direction on the main surface of the semiconductor substrate, the first conductive film being in electrical contact with the semiconductor substrate.

2. The passive element according to claim 1,
wherein the first insulating film is provided on a first region in the main surface of the semiconductor substrate,
wherein the first conductive film is provided on a second region adjacent to the first region in the first direction, the first conductive film is in ohmic contact with the main surface of the semiconductor substrate, and the first conductive film has an electric resistivity lower than an electric resistivity of the semiconductor substrate,
the passive element further comprising:
a second insulating film provided on a third region adjacent to the second region in the first direction in the main surface of the semiconductor substrate; and
a second metal pad provided on the second insulating film,
wherein the second region is located between the first region and the third region.

3. The passive element according to claim 2,
wherein the first metal pad includes a first protrusion protruding toward the second metal pad, and
wherein the first conductive film includes a first indentation surrounding the first protrusion from three sides.

4. The passive element according to claim 3,
wherein the second metal pad includes a second protrusion protruding toward the first protrusion, and
wherein the first conductive film further includes a second indentation surrounding the second protrusion from three sides.

5. The passive element according to claim 2, further comprising:
a second conductive film provided on a fourth region in the main surface of the semiconductor substrate, the second conductive film being in contact with the main surface of the semiconductor substrate, and the second conductive film having an electrical resistivity lower than the electrical resistivity of the semiconductor substrate;
a third insulating film provided on a fifth region in the main surface of the semiconductor substrate; and
a third metal pad provided on the third insulating film,
wherein the first region to the fifth region are arranged in this order along the first direction of the first region and the second region.

6. The passive element according to claim 2,
wherein a width of the first conductive film in the first direction of the first region and the second region is larger than a width of the first metal pad in a same direction.

7. A passive element comprising:
a semiconductor substrate having a p-type or n-type conductivity and having a main surface and a back surface;
a back surface metal film provided on the back surface of the semiconductor substrate;
a conductive film in contact with the main surface of the semiconductor substrate;
a first insulating film provided on the conductive film and having an end in a first direction;
a first metal pad provided on the first insulating film;
a first conductor extending from the first metal pad in the first direction.

8. The passive element according to claim 7,
wherein the conductive film is provided on a region including a first region and a second region adjacent to the first region in the first direction, and has an electric resistivity lower than an electric resistivity of the semiconductor substrate,
wherein the first insulating film is provided on the first region.

9. The passive element according to claim 2,
wherein the semiconductor substrate has an electrical resistivity of 1.0×10⁻⁴ Ω·cm or more and 1 Ω·cm or less.

10. The passive element according to claim 1,
wherein the first metal pad extends along a second direction intersecting the first direction, and
wherein a length of the first metal pad in the second direction are greater than a width of the first metal pad in the first direction.

11. An electronic device comprising:
a housing including a signal terminal and a base having conductivity;
a semiconductor element mounted on the base, the semiconductor element including a signal electrode and a ground electrode, the ground electrode being conductively bonded to the base; and
the passive element according to claim 2 mounted on the base,
wherein the first metal pad of the passive element is electrically connected with the signal terminal by a second conductor, and
wherein the semiconductor substrate of the passive element is conductively bonded to the base.

12. An electronic device comprising:
a housing including a signal terminal and a base having conductivity;
a semiconductor element mounted on the base, the semiconductor element including a signal electrode and a ground electrode, the ground electrode being conductively bonded to the base;
a passive element including:
a semiconductor substrate mounted on the base, having a p-type or n-type conductivity and having a main surface and a back surface;
a back surface metal film provided on the back surface of the semiconductor substrate;
a first insulating film provided on a first region in the main surface of the semiconductor substrate;
a first metal pad provided on the first insulating film;
a first conductor connected to the first metal pad and extending in a first direction from the first metal pad;
a first conductive film provided on a second region, the second region being adjacent to the first region in the first direction in the main surface of the semiconductor substrate and located under the first conductor, the first conductive film being in ohmic contact with the main surface of the semiconductor substrate and having an electrical resistivity lower than an electrical resistivity of the semiconductor substrate;
a second insulating film provided on a third region adjacent to the second region in the first direction; and
a second metal pad connected with the first conductor and provided on the second insulating film,
a second conductor electrically connecting the first metal pad of the passive element and the signal terminal; and
a third conductor electrically connecting the second metal pad of the passive element and the signal electrode of the semiconductor element.

13. The passive element according to claim 8,
wherein the semiconductor substrate has an electrical resistivity of 1.0×10⁻⁴ Ω·cm or more and 1 Ω·cm or less.

14. The passive element according to claim 7,
wherein the first metal pad extends along a second direction intersecting the first direction, and
wherein a length of the first metal pad in the second direction are greater than a width of the first metal pad in the first direction.

15. An electronic device comprising:
a housing including a signal terminal and a base having conductivity;
a semiconductor element mounted on the base, the semiconductor element including a signal electrode and a ground electrode, the ground electrode being conductively bonded to the base; and
the passive element according to claim 8 mounted on the base,
wherein the first metal pad of the passive element is electrically connected with the signal terminal by a second conductor, and
wherein the semiconductor substrate of the passive element is conductively bonded to the base.
